(19) United States
(12) Patent Application Publication
(10) Pub. No.: US 2009/0061633 A1
(43) Pub. Date: Mar. 5, 2009

(54) METHOD OF MANUFACTURING SEMICONDUCTOR DEVICE

(75) Inventors: Yoshihiro NAKATA, Kawasaki (JP); Tadahiro IMADA, Kawasaki (JP); Shirou OZAKI, Kawasaki (JP); Yasushi KOBAYASHI, Kawasaki (JP); Kohta YOSHIKAWA, Kawasaki (JP); Ei YANO, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/199,297

(22) Filed: Aug. 27, 2008

(30) Foreign Application Priority Data
Aug. 31, 2007 (JP) 2007-225627
Jun. 4, 2008 (JP) 2008-146619

(51) Int. Cl. H01L 21/311

(52) U.S. Cl. 438/694; 257/E21.249

(57) ABSTRACT

According to an aspect of an embodiment, a method of manufacturing a semiconductor device has forming an insulating layer comprising silica-based insulating material, processing the insulating layer, hydrophobizing the insulating layer by applying a silane compound to act on the insulating layer; and irradiating the insulating layer with light or an electron beam.

### BACKGROUND

There is an art related to methods of manufacturing semiconductor devices including a dry-etching a silica-based insulating layer.

Increases in the integration and device density of semiconductor integrated circuits increase the demand for multilayer semiconductor devices. An increase in integration leads to a reduction in wiring distance. Therefore, it may cause an increase in capacitance between wires causes wiring delay.

Wiring delay is affected by the resistance of wires and the capacitance between the wires and is given by the following formula:

T∝CR

wherein T represents the wiring delay, R represents the wire resistance, and C represents the capacitance between the wires and is given by the following equation:

C=∈₀∈ᵣS/d

where d represents the distance between the wires, S represents the electrode area (the area of opposed side surfaces of the wires), ∈ᵣ represents the dielectric constant of an insulating material disposed between the wires, and ∈₀ represents the dielectric constant of vacuum. Therefore, a reduction in the dielectric constant of the insulating material is effective in reducing the wiring delay.

Conventional insulating materials used are inorganic materials such as silicon dioxide (SiO₂), silicon nitride (SiN), and phosphorus silicate glass (PSG) and organic polymers such as polyimides. CVD SiO₂ layers, which are most commonly used in semiconductor devices, have a dielectric constant of about 4. SiOF layers, which are low-dielectric constant CVD layers and are under study, have a dielectric constant of about 3.3 to 3.5. However, the SiOF layers are highly hygroscopic; hence, the dielectric constant thereof increases with the absorption of moisture.

In recent years, porous insulating layers, which are insulating materials having lower dielectric constants, are attracting much attention. The porous insulating layers are formed in such a manner that organic resins that are vaporizable or decomposable by heating are added to materials for forming low-dielectric constant coatings and then vaporized or decomposed by heating during the formation of the porous insulating layers.

Silica-based insulating layers, particularly porous insulating layers, suffer from work damage in steps of forming multi-level wirings and therefore are increased in effective dielectric constant. Therefore, the following technique has been proposed: a technique in which a damaged layer is repaired in such a manner that a dry-etched interlayer insulating layer is surface-treated with a silazane compound and then vacuum-dried. Furthermore, the following technique has been proposed: a technique in which an insulating layer treated with a silane compound such as a silazane, an alkoxysilane, or an acetoxysilane such that a damaged layer is repaired.

### SUMMARY

According to an aspect of an embodiment, a method of manufacturing a semiconductor device has forming an insulating layer comprising silica-based insulating material, processing the insulating layer, hydrophobizing the insulating layer by applying a silane compound to act on the insulating layer; and irradiating the insulating layer with light or an electron beam.

### BRIEF DESCRIPTION OF THE DRAWINGS

FIG. 1 is a flowchart showing a method of manufacturing a semiconductor device according to a first embodiment;

FIGS. 2A to 2C are sectional views showing steps of the method according to the first embodiment;

FIGS. 3A to 3C are sectional views showing steps of the method according to the first embodiment;

FIGS. 4A to 4C are sectional views showing steps of a method of manufacturing a semiconductor device according to a second embodiment;

FIGS. 5A and 5B are sectional views showing steps of the method according to the second embodiment;

FIGS. 6A and 6B are sectional views showing steps of the method according to the second embodiment;

FIGS. 7A and 7B are sectional views showing steps of the method according to the second embodiment;

FIGS. 8A and 8B are sectional views showing steps of the method according to the second embodiment;

FIG. 9 is a sectional view showing a step of the method according to the second embodiment;

FIG. 10 is a sectional view showing a step of the method according to the second embodiment;

FIG. 11 is a sectional view showing a step of the method according to the second embodiment;

FIG. 12 is a sectional view showing a step of the method according to the second embodiment;

FIG. 13 is a sectional view showing a step of the method according to the second embodiment;

FIG. 14 is a sectional view showing a step of the method according to the second embodiment;

FIG. 15 is sectional view showing a step of the method according to the third embodiment;

FIGS. 16A to 16D are sectional views showing a step of the method according to the third embodiment;

FIGS. 17A and 17B are sectional views showing a step of the method according to the fourth embodiment;

FIGS. 18A and 18B are sectional views showing a step of the method according to the fourth embodiment;

FIG. 19 is a sectional view showing a step of the method according to the fourth embodiment;

FIG. 20 is a sectional view showing a step of the method according to the fourth embodiment;

FIG. 21 is a sectional view showing a step of the method according to the fourth embodiment;

FIGS. 22A and 22B are sectional views showing a step of the method according to the fifth embodiment;

FIGS. 23A and 23B are sectional views showing a step of the method according to the fifth embodiment;

FIG. 24 is a sectional view showing a step of the method according to the fifth embodiment;

FIG. 25 is a sectional view showing a step of the method according to the fifth embodiment;

FIG. 26 is a sectional view showing a step of the method according to the fifth embodiment;

FIGS. 27A to 27D are sectional views showing steps of a method for preparing an evaluation sample used to demonstrate advantages of the present technique.

### DESCRIPTION OF THE PREFERRED EMBODIMENTS

### First Embodiment

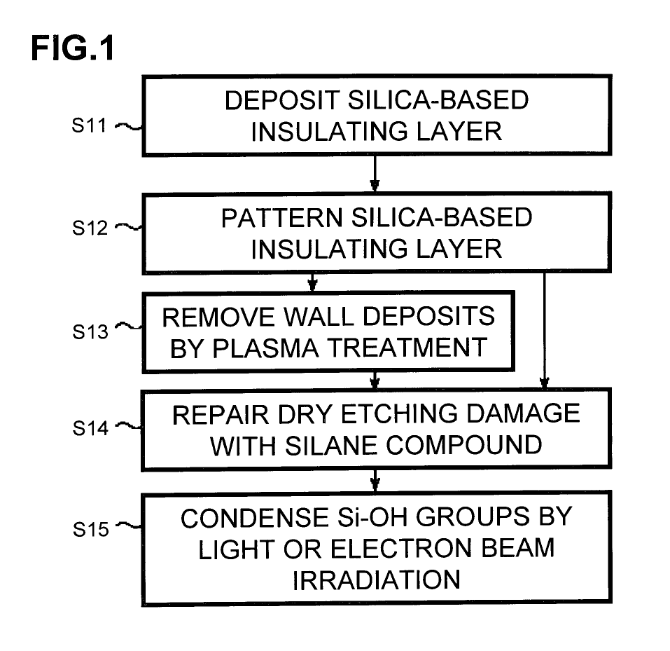

A method of manufacturing a semiconductor device according to a first embodiment will now be described with reference to FIGS. 1, 2A to 2C, and 3A to 3C.

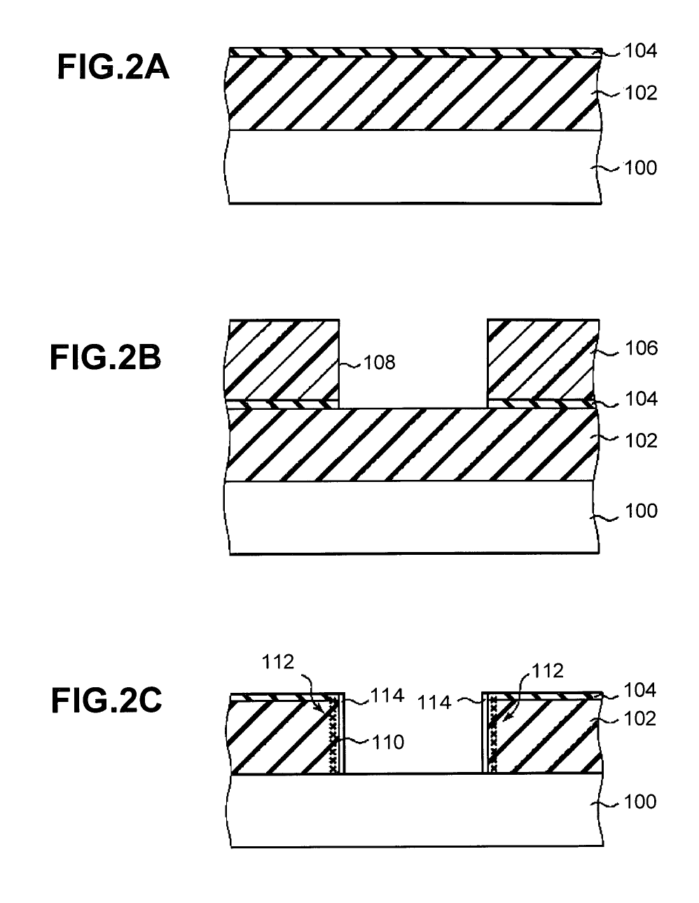

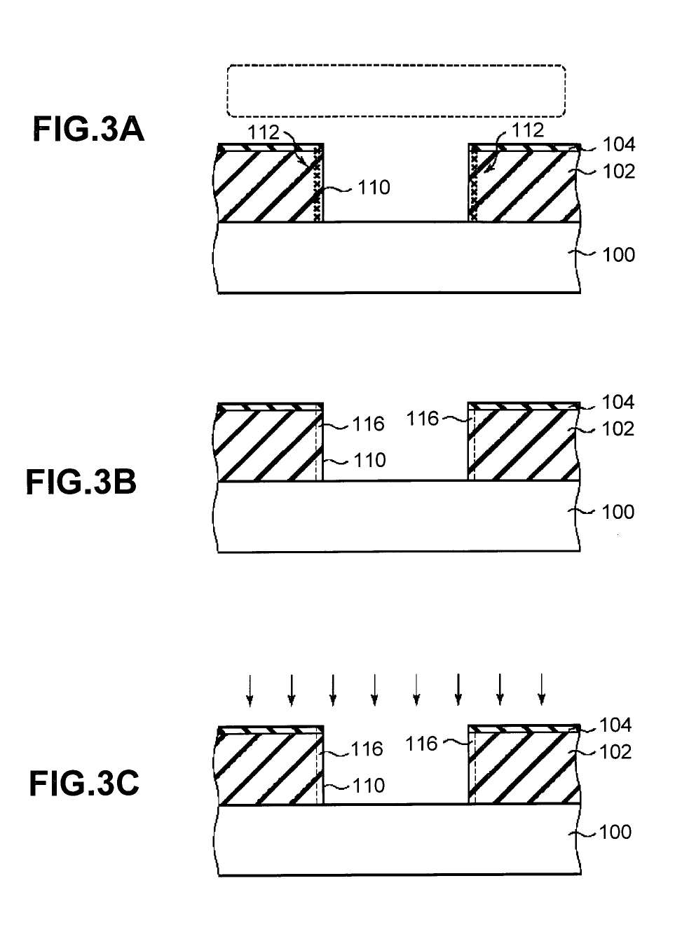

FIG. 1 is a flowchart showing the method. FIGS. 2A to 2C and 3A to 3C are sectional views showing steps of the method.

With reference to FIG. 1, the method includes a step of depositing a silica-based insulating layer (Step S11), a step of patterning the silica-based insulating layer (Step S12), a step of removing wall deposits by plasma treatment (Step S13), a step of repairing dry etching damage with a silane compound (Step S14), and a step of condensing Si—OH groups by light or electron beam irradiation (Step S15).

These steps will now be described in detail with reference to FIGS. 2A to 2C and 3A to 3C.

The silica-based insulating layer 102 is deposited on a base substrate 100 (Step 11). Examples of the base substrate 100 include semiconductor substrates, such as silicon substrates, including MIS transistors, one or more wiring layers, and the like.

Examples of the silica-based insulating layer 102 include plasma-CVD layers such as plasma SiO₂ layers, plasma SiN layers, plasma SiC:H layers, plasma SiC:O:H layers, plasma SIC:H:N layers, and plasma SiOC layers; coating-type insulating layers such as organic SOG layers and porous silica layers; and similar layers. The term “SIC:H layer” herein means a SiC layer containing hydrogen (H). The term “SiC:O:H layer” herein means a SiC layer containing oxygen (O) and hydrogen (H). The term “SiC:H:N layer” herein means a SiC layer containing hydrogen (H) and nitrogen (N). In particular, the coating-type insulating layers such as porous silica layers are preferable because of their low dielectric constants.

Examples of porous silica include template-type porous silica materials having pores formed by decomposing a thermally decomposable resin mixed with organic SOG and non-template-type porous silica materials having pores formed by particles.

Examples of the non-template-type porous silica materials include NCS series available from Catalysts & Chemicals Ind. Co., Ltd. and e LKD series available from JSR Corporation.

Other preferable examples of the non-template-type porous silica materials include liquid compositions containing an organic silicon compound obtained by hydrolysis in the presence of tetraalkylammonium hydroxide (TAAOH). Materials made from the liquid compositions have an elastic modulus of 10 GPa or more, a hardness of 1 GPa or more, and a good balance between low dielectric constant and high strength. Examples of the organic silicon compound include tetraalkoxysilanes, trialkoxysilanes, methyltrialkoxysilanes, ethyltrialkoxysilanes, propyltrialkoxysilanes, phenyltrialkoxysilanes, vinyltrialkoxysilanes, allyltrialkoxysilanes, glycidyltrialkoxysilanes, dialkoxysilanes, dimethyldialkoxysilanes, diethyldialkoxysilanes, dipropyldialkoxysilanes, diphenyldialkoxysilanes, divinyldialkoxysilanes, diallyldialkoxysilanes, diglycidyldialkoxysilanes, phenylmethyldialkoxysilanes, phenylethyldialkoxysilanes, phenylpropyltrialkoxysilanes, phenylvinyldialkoxysilanes, phenylallyldialkoxysilanes, phenylglycidyldialkoxysilanes, methylvinyldialkoxysilanes, ethylvinyldialkoxysilanes, and propylvinyldialkoxysilanes.

A coating solvent used to form a coating-type porous silica layer is capable of dissolving a siloxane resin that is a porous silica precursor and is not particularly. Examples of the coating solvent include alcohols such as methyl alcohol, ethyl alcohol, n-propyl alcohol, i-propyl alcohol, n-butyl alcohol, i-butyl alcohol, and t-butyl alcohol; phenols such as phenol, cresol, diethylphenol, triethylphenol, propylphenol, nonylphenol, vinylphenol, and allylphenol; ketones such as cyclohexanone, methyl isobutyl ketone, and methyl ethyl ketone; cellosolves such as methylcellosolve and ethylcellosolve; hydrocarbons such as hexane, octane, and decane; and glycols such as propylene glycol, propylene glycol monomethyl ether, propylene glycol monomethyl ether acetate.

An insulating layer made from a coating-type insulating material can be formed through, for example, a step of applying the insulating material to a base substrate, a step of heating the base substrate at a temperature of 80° C. to 350° C., and a step of curing the base substrate at a temperature of 350° C. to 450° C. The heating step and the curing step are preferably performed in an inert atmosphere with an oxygen content of 100 ppm or less. This is because the moisture resistance of the insulating layer is prevented from being deteriorated by oxidation.

As shown in FIG. 2A, a hard mask 104 made of, for example, SiO₂ is formed on the silica-based insulating layer 102 by, for example, a CVD process.

A photoresist layer 106 is formed on the hard mask 104. The photoresist layer 106 has a first opening 108 formed in a predetermined region by photolithography.

As shown in FIG. 2B, the hard mask 104 is dry-etched in such a manner that the photoresist layer 106 is used as a mask, whereby the first opening 108 is transferred to the hard mask 104.

The photoresist layer 106 is removed by ashing using, for example, oxygen plasma.

The silica-based insulating layer 102 is dry-etched through the patterned hard mask 104, whereby a second opening 110 is formed in the silica-based insulating layer 102 (Step S12). A process for dry-etching the silica-based insulating layer 102 is capable of forming wiring grooves and/or via-holes and is not particularly limited. The silica-based insulating layer 102 can be dry-etched in a vacuum chamber in which the following gas or mixture is plasmatized at, for example, a pressure of 50 mTorr and a power of 200 W: one or more of gaseous fluorohydrocarbons such as CF₄, CHF₃, C₂F₆, C₃F₈, and C₄F₁₀ or a gas mixture containing at least one of the gaseous fluorohydrocarbons and at least one of argon (Ar), nitrogen (N₂), oxygen (O₂), and hydrogen (H₂).

In the above dry etching step, damaged layers 112 are formed in the wall of the second opening 110 as shown with crosses in FIG. 2C. The damaged layers 112 are regions in which bonds are broken due to plasma damage and which are likely to adsorb moisture. The damaged layers 112 contain Si—OH groups.

By-products produced in the dry etching step are deposited on the wall of the second opening 110, whereby wall deposits 114 are formed on the wall thereof as shown in FIG. 2C. In the case where the silica-based insulating layer 102 is dry-etched with, for example, an etching gas containing fluorine, the wall deposits 114 contain CFₓ polymers.

The patterned silica-based insulating layer 102 is treated with the plasma generated from gas containing one or more of oxygen, argon, hydrogen, and nitrogen as required (Step S13). This allows the wall deposits 114 to be removed from the wall of the second opening 110 as shown in FIG. 3A.

The above plasma treatment is to remove the wall deposits 114. If the wall deposits 114 remain on the wall of the second opening 110, the effect of repairing the damage described below is insufficient. Therefore, in the case where the silica-based insulating layer 102 is dry-etched with an etching gas containing fluorine, the plasma treatment is preferably performed.

The silica-based insulating layer 102 is patterned using the hard mask 104 having a pattern transferred from the photoresist layer 106 as described above. The silica-based insulating layer 102 may be patterned in such a manner that the photoresist layer 106 is used as a mask instead of the hard mask 104. In this case, the photoresist layer 106 is removed after the completion of the second opening 110. The photoresist layer 106 is usually removed by ashing using oxygen plasma. This provides the same effect as that obtained from Step S13. If the wall deposits 114 can be sufficiently removed by ashing together with the photoresist layer 106, the plasma treatment of Step S13 need not necessarily be performed. The plasma treatment of Step S13 may be performed in addition to oxygen plasma ashing.

The wall deposits 114 may be removed with a chemical such as hydrofluoric acid, ammonium fluoride, or ammonium phosphate instead of performing the plasma treatment of Step S13.

The damage of the silica-based insulating layer 102 that is caused by dry etching performed to form the second opening 110 is repaired with a silane compound (Step S14).

This allows the damaged layers 112 to be repaired, whereby repaired layers 116 are formed as shown in FIG. 3B.

In this operation, the Si—OH groups, which are produced by dry etching, are allowed to react with the silane compound. A process for allowing the Si—OH groups to react with the silane compound is not particularly limited and any process may be used. The following process is preferably used: a spin-coating process or a vapor process in which the treatment with the silane compound is performed at atmospheric pressure or in a vacuum. In particular, the vapor process is particularly preferable because the vapor process is insensitive to surface tension.

In the vapor process, the base substrate 100 is preferably heated to a temperature of 50° C. to 350° C. such that the silane compound is diffused in the silica-based insulating layer 102 and repaired portions are reinforced. In the spin-coating process, the silica-based insulating layer 102 is treated at room temperature with a spin coater and may be then baked such that the repaired portions are reinforced. In this case, the silica-based insulating layer 102 is preferably baked at a temperature or temperatures within a range from 50° C. to 350° C.

The treatment temperature of the silica-based insulating layer 102 is preferably selected within a range from 50° C. to 350° C. depending on the type of the silane compound. The upper limit of the treatment temperature thereof depends on the boiling point of the silane compound and therefore is set to be lower than or equal to the boiling point of the silane compound. The reason why the lower limit thereof is set to 50° C. is that the damage of the silica-based insulating layer 102 cannot be sufficiently repaired with the silane compound at a temperature lower than 50° C.

The silane compound, which is used to repair the damage of the silica-based insulating layer 102, has a functional group reactable with the Si—OH groups and is not particularly limited. Examples of the silane compound include silazanes such as dimethyldisilazane, tetramethyldisilazane, and hexamethyldisilazane; silylamides such as bis(trimethylsilyl) acetamide and bis(triethylsilyl) acetamide; alkoxysilanes such as trimethoxysilane, triethoxysilane, methyltrimethoxysilane, methyltriethoxysilane, dimethylmethoxysilane, dimethylethoxysilane, trimethylmethoxysilane, trimethylethoxysilane, ethyltrimethoxysilane, ethyltriethoxysilane, diethylmethoxysilane, diethylethoxysilane, triethylmethoxysilane, triethylethoxysilane, propyltrimethoxysilane, propyltriethoxysilane, dipropylmethoxysilane, dipropylethoxysilane, tripropylimethoxysilane, tripropylethoxysilane, phenyltrimethoxysilane, phenyltriethoxysilane, diphenylmethoxysilane, diphenylethoxysilane, triphenylmethoxysilane, triphenylethoxysilane, phenylmethylmethoxysilane, phenylmethylethoxysilane, dimethylphenylmethoxysilane, dimethylphenylethoxysilane, diphenylmethylmethoxysilane, and diphenylmethylethoxysilane; and acetoxysilanes such as triacetoxysilane, triethoxysilane, methyltriethoxysilane, dimethylacetoxysilane, trimethylacetoxysilane, ethyltriacetoxysilane, diethylacetoxysilane, triethylacetoxysilane, dipropylacetoxysilane, tripropylacetoxysilane, phenyltriacetoxysilane, diphenylacetoxysilane, triphenylacetoxysilane, phenylmethylacetoxysilane, dimethylphenylacetoxysilane, and diphenylmethyltriacetoxysilane.

The repair of the damage allows the Si—OH groups, which are present in the damaged layers 112, to be converted into Si—CH₃ groups, resulting in an enhancement in hydrophobicity. However, it is difficult to convert all the Si—OH groups into the Si—CH₃ groups because the silane compound has a large molecular weight and therefore is sterically-hindered. If the silica-based insulating layer 102 is exposed to air, the remaining Si—OH groups adsorb moisture. This causes an increase in the dielectric constant of the silica-based insulating layer 102.

According to the method of this embodiment, the remaining Si—OH groups are condensed (dehydrocondensed) into Si—O—Si groups after the damage repair so as to be prevented from adsorbing moisture (Step S15). The remaining Si—OH groups can be condensed in such a manner that the silica-based insulating layer 102 is irradiated with light or an electron beam while the base substrate 100 is being heated at 30° C. to 400° C. as shown in FIG. 3C.

A lamp used for the condensation of the remaining Si—OH groups can emit light with a wavelength of 170 to 700 nm and is not particularly. Examples of the lamp include excimer lamps, mercury lamps, and metal halide lamps. The temperature of the base substrate 100 is preferably 30° C. to 400° C. during light irradiation.

An atmosphere used to condense the remaining Si—OH groups preferably has an oxygen content of 150 ppm or less and may contain one or more of nitrogen, helium (He), and argon. Alternatively a vacuum atmosphere (a low-pressure atmosphere) may be used for the condensation thereof. In the case of such a vacuum atmosphere, one or more of nitrogen, helium, and argon may be introduced into a vacuum chamber in such a manner that the pressure in the vacuum chamber is adjusted to a predetermined value with one or more mass flow meters.

In the condensation of the Si—OH groups by electron beam irradiation, the silica-based insulating layer 102 is preferably irradiated with an electron beam having an acceleration voltage of 1 to 15 kV in a vacuum. When the acceleration voltage of the electron beam is less than 1 kV, no sufficient effect can be expected. When the acceleration voltage thereof is greater than 15 kV, the silica-based insulating layer 102 may be damaged.

The treatment temperature during light or electron beam irradiation is preferably selected within a range from 30° C. to 400° C. depending on the type of the silica-based insulating layer 102. The upper limit of the treatment temperature depends on the upper temperature limit of the silica-based insulating layer 102 and is less than the upper temperature limit thereof. The reason why the lower limit of the treatment temperature is set to 30° C. is that condensation reaction does not occur at a temperature lower than 30° C.

Since the Si—OH groups are subjected to condensation after the damage is repaired with the silane compound as described above, the hygroscopicity of the silica-based insulating layer 102 can be greatly reduced. This prevents the silica-based insulating layer 102 from adsorbing moisture even if the silica-based insulating layer 102 is exposed to air, that is, this prevents the dielectric constant of the silica-based insulating layer 102 from being increased due to the adsorption of moisture on the silica-based insulating layer 102.

According to this embodiment, the dielectric constant of the silica-based insulating layer 102 can be prevented from being increased due to the damage caused by dry etching even if the silica-based insulating layer 102 is exposed to air.

### Second Embodiment

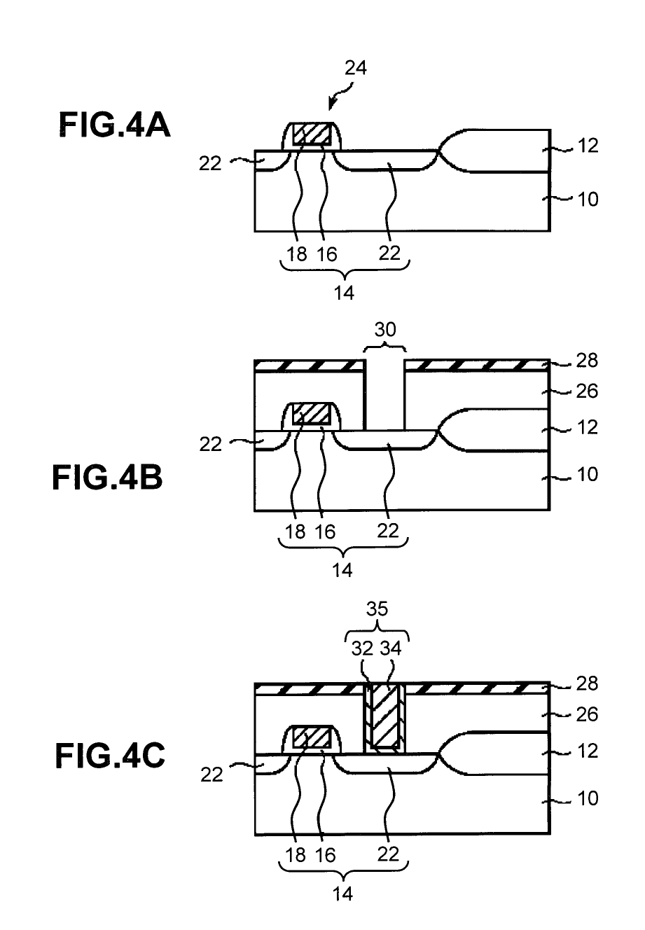

A method of manufacturing a semiconductor device according to a second embodiment will now be described with reference to FIGS. 4A to 14. In these figures, the same members as those, used to describe the method of manufacturing the semiconductor device according to the first embodiment, shown in FIGS. 1 to 3C have the same reference numerals and will be briefly described or will not be described.

FIGS. 4A to 14 are sectional views showing steps of the method of this embodiment.

The method of this embodiment is more specific than that of the first embodiment.

An isolation layer 12 for defining an element region 14 is formed on a semiconductor substrate 10 which is, for example, silicon substrate by, for example, a local oxidation of silicon (LOCOS) process. The isolation layer 12 may be formed by a shallow trench isolation (STI) process.

A MOS transistor 24 is formed on the element region 14 by a process similar to that of manufacturing an ordinary MOS transistor. As shown in FIG. 4A, the MOS transistor 24 includes a gate electrode 18 disposed above the semiconductor substrate 10 with a gate insulating layer 16 located therebetween and also includes source/drain regions 22, disposed in the semiconductor substrate 10, lying on both sides of the gate electrode 18.

For example, a silicon dioxide (SiO₂) layer is formed over the semiconductor substrate 10 and the MOS transistor 24 by, for example, a CVD process.

A surface of the silicon dioxide layer is planarized by, for example, a chemical mechanical polishing (CMP) process, whereby a first interlayer insulating layer 26, made of silicon dioxide, having a flat surface is formed.

Silicon nitride (SiN) is deposited on the first interlayer insulating layer 26 by, for example, a plasma-enhanced CVD process, whereby a stopper layer 28 is formed. The stopper layer 28 is made of silicon nitride and has a thickness of, for example, 50 nm. The stopper layer 28 functions as a polishing stopper during CMP in a subsequent step and also functions as an etching stopper during the formation of first wiring grooves 46 in a second interlayer insulating layer 38 in another subsequent step. The stopper layer 28 may be made of SiC:H, SiC:O:H, or SiC:H other than silicon nitride.

As shown in FIG. 4B, contact holes 30 are formed by photolithography and dry etching so as to extend through the stopper layer 28 and the first interlayer insulating layer 26 to the source/drain regions 22.

Titanium nitride (TiN) is deposited over the stopper layer 28 by, for example, a sputtering process, whereby a first barrier metal layer 32 is formed. The first barrier metal layer 32 is made of TiN and has a thickness of, for example, 50 nm.

A tungsten (W) layer 34 with a thickness of, for example, 1 μm is formed on the first barrier metal layer 32 by, for example, a CVD process.

As shown in FIG. 4C, the tungsten layer 34 and the first barrier metal layer 32 are polished by, for example, a CMP process such that the stopper layer 28 is exposed, whereby first contact plugs 35 each including a portion of the first barrier metal layer 32 and a portion of the tungsten layer 34 are formed in the contact holes 30.

SiC:O:H is deposited on the stopper layer 28, in which the first contact plugs 35 are arranged, by, for example, a plasma-enhanced CVD process, whereby a first insulating layer 36 is formed. The first insulating layer 36 is made of SiC:O:H and has a thickness of, for example, 30 nm. The first insulating layer 36 is a dense SiC film containing oxygen and hydrogen and functions as a barrier layer for preventing the diffusion of moisture and the like.

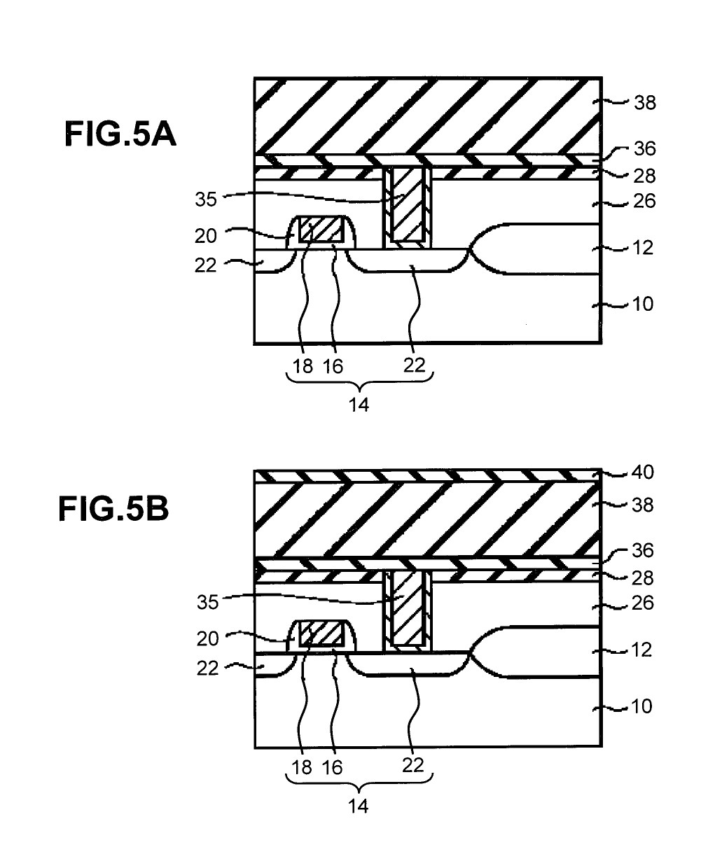

As shown in FIG. 5A, the second interlayer insulating layer 38 is formed on the first insulating layer 36. The second interlayer insulating layer 38 is a porous silica material and has a thickness of, for example, 160 nm. The following material and process can be used to form the second interlayer insulating layer 38: one of the porous silica materials and the process used to form the silica-based insulating layer 102 in the method according to the first embodiment.

As shown in FIG. 5B, silicon dioxide (SiO₂) is deposited on the second interlayer insulating layer 38 by, for example, a plasma-enhanced CVD process, whereby a second insulating layer 40 is formed. The second insulating layer 40 is silicon dioxide and has a thickness of, for example, 30 nm.

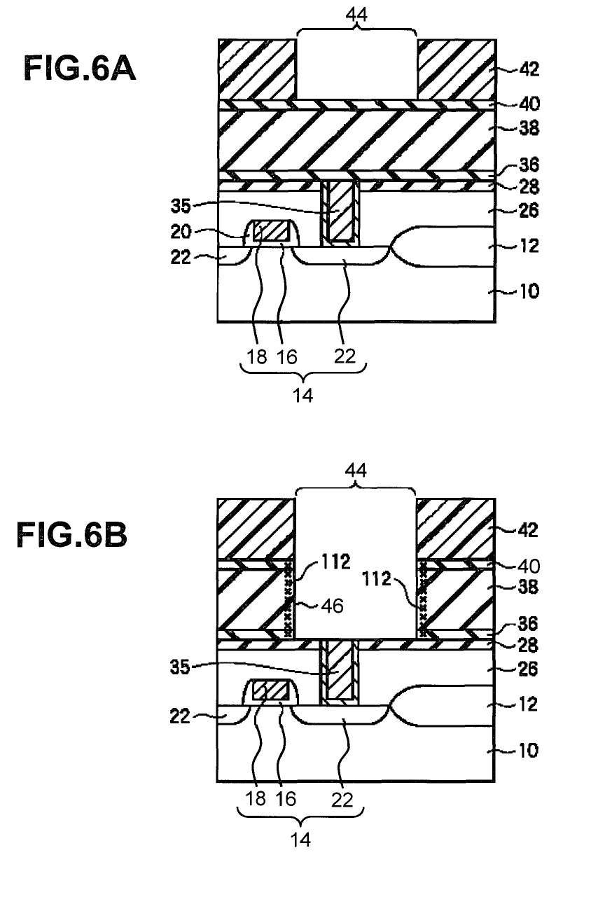

As shown in FIG. 6A, a first photoresist layer 42 is formed on the second insulating layer 40. The first photoresist layer 42 has first openings 44 formed by photolithography. Through the first openings 44, regions for forming first wires 51 which have a width of about 100 nm and which are spaced at a distance of about 100 nm are exposed.

As shown in FIG. 6B, the second insulating layer 40, the second interlayer insulating layer 38, and the first insulating layer 36 are sequentially dry-etched with, for example, a CF₄ gas and a CHF₃ gas in such a manner that the first photoresist layer 42 and the stopper layer 28 are used as a mask and a stopper, respectively, whereby the first wiring grooves 46 for forming the first wires 51 are formed. The first wires 51 extend through the second insulating layer 40, the second interlayer insulating layer 38, and the first insulating layer 36. In this dry etching step, damaged layers 112 containing Si—OH groups are formed in the walls of the first wiring grooves 46 as shown with crosses in FIG. 6B.

The first photoresist layer 42 is removed by, for example, oxygen plasma ashing. Even if wall deposits are formed on the walls of the first wiring grooves 46 by dry etching during the formation of the first wiring grooves 46, the wall deposits can be removed in this ashing step.

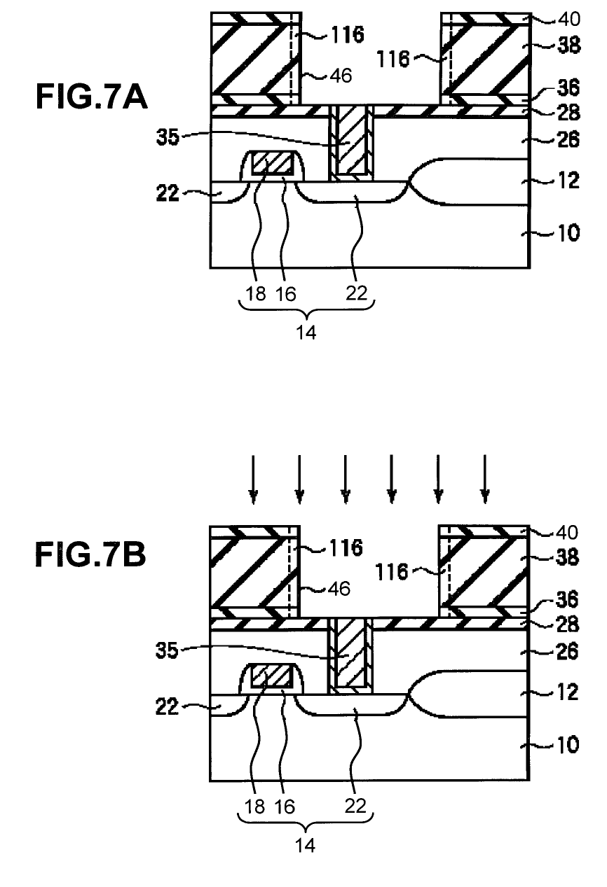

After 3 cc of a silane compound, for example, hexamethyldisilazane is dripped onto the second insulating layer 40 and the second insulating layer 40 is then subjected to spin coating at 1,000 rpm for 60 seconds, the semiconductor substrate 10 is baked, for example, at 120° C. for 60 seconds and further baked at 250° C. for 60 seconds with a hot plate. This allows the Si—OH groups, which are produced by dry etching during the formation of the first wiring grooves 46, to be converted into Si—CH₃ groups, whereby the damaged layers 112, which are present in the walls of the first wiring grooves 46, are repaired. This results in the formation of repaired layers 116 as shown in FIG. 7A.

The same silane compound and process used to repair the damaged layers 112 described in the first embodiment may be used in this step.

As shown in FIG. 7B, the second insulating layer 40 is irradiated with ultraviolet rays having a wavelength of, for example, 200 to 600 nm for ten minutes using, for example, a UVL-7000 H4-N high-pressure mercury lamp available from Ushio Inc. in such a manner that the semiconductor substrate 10 is heat to, for example, 400° C. in a nitrogen atmosphere. This allows the remaining Si—OH groups to be converted into Si—O—Si groups by condensation, so that the adsorption of moisture by the remaining Si—OH groups is prevented.

The same process and conditions as those used to condense the Si—OH groups shown in the first embodiment may be used in this step. Electron beam irradiation may be performed in this step instead of light irradiation in the same manner as that shown in the first embodiment.

Tantalum nitride (TaN) is deposited over the second insulating layer 40 by, for example, a sputtering process, whereby a second barrier metal layer 48 is formed. The second barrier metal layer 48 is tantalum nitride and has a thickness of, for example, 10 nm. The second barrier metal layer 48 prevents copper from diffusing from copper wires, formed in a subsequent step, into the insulating layers.

Copper is deposited on the second barrier metal layer 48 by, for example, a sputtering process, whereby a first seed layer (not shown) is formed. The first seed layer is copper and has a thickness of, for example, 10 nm.

A first copper coating is deposited on the first seed layer by, for example, an electroplating process, whereby a first copper layer 50 is formed. The first copper layer 50 includes the first seed layer and the first copper coating and has a thickness of, for example, 600 nm.

A portion of the second barrier metal layer 48 that is located on the second insulating layer 40 and a portion of the first copper layer 50 that is located above the second insulating layer 40 are removed by a CMP process, whereby the first wires 51 are formed in the first wiring grooves 46. The first wires 51 include portions of the second barrier metal layer 48 that remain in the first wiring grooves 46 and portions of the first copper layer 50 that remain therein. A process for forming the first wires 51 as described above is referred to as a single damascene process.

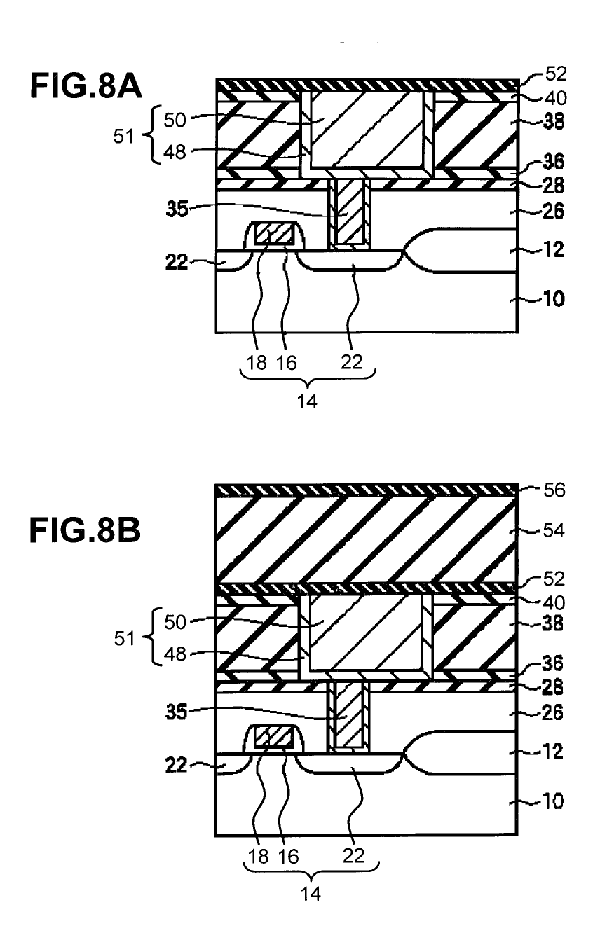

As shown in FIG. 8A, SiC:O:H is deposited over the second insulating layer 40 by, for example, a CVD process, whereby a third insulating layer 52 is formed. The third insulating layer 52 is SiC:O:H and has a thickness of, for example, 30 nm. The third insulating layer 52 functions as a barrier layer for preventing the diffusion of moisture and the diffusion of copper from the first wires 51.

A third interlayer insulating layer 54 is formed on the third insulating layer 52 using a porous silica material. The third interlayer insulating layer 54 can be formed in the same manner as that used to form the second interlayer insulating layer 38. The third interlayer insulating layer 54 has a thickness of, for example, 180 nm.

As shown in FIG. 8B, silicon dioxide (SiO₂) is deposited on the third interlayer insulating layer 54 by, for example, a plasma-enhanced CVD process, whereby a fourth insulating layer 56 is formed. The fourth insulating layer 56 is made of silicon dioxide and has a thickness of, for example, 30 nm.

A fifth interlayer insulating layer 58 is formed on the fourth insulating layer 56 using a porous silica material. A process for forming the fifth interlayer insulating layer 58 may be the same as that used to form the second interlayer insulating layer 38. The fifth interlayer insulating layer 58 has a thickness of, for example, 160 nm.

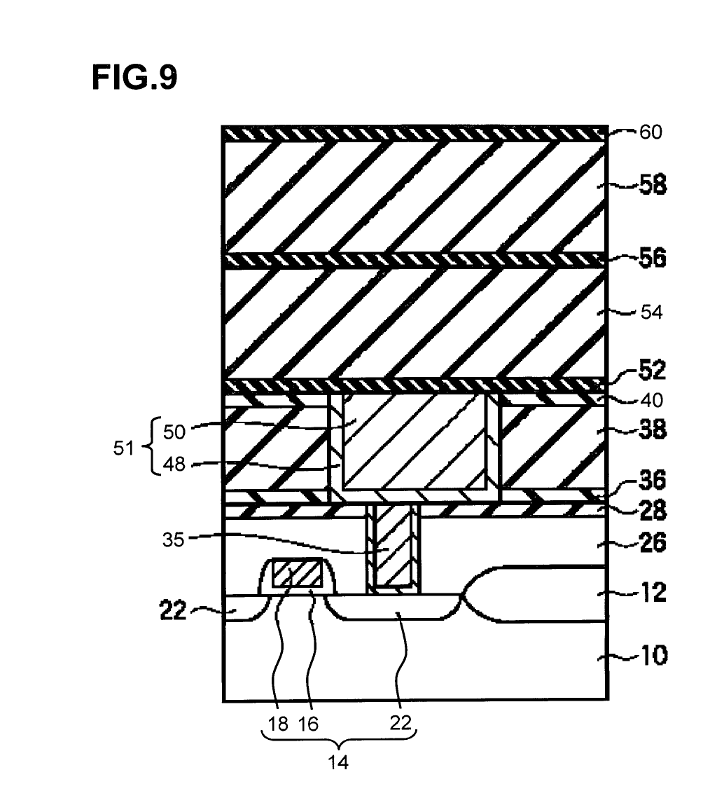

As shown in FIG. 9, silicon dioxide (SiO₂) is deposited on the fifth interlayer insulating layer 58 by, for example, a plasma-enhanced CVD process, whereby a fifth insulating layer 60 is formed. The fifth insulating layer 60 is made of silicon dioxide and has a thickness of, for example, 30 nm.

A second photoresist layer 62 is formed on the fifth insulating layer 60. The second photoresist layer 62 has second openings 64 formed by photolithography. Through the second openings 64, regions for forming via-holes extending to the first wires 51 are exposed.

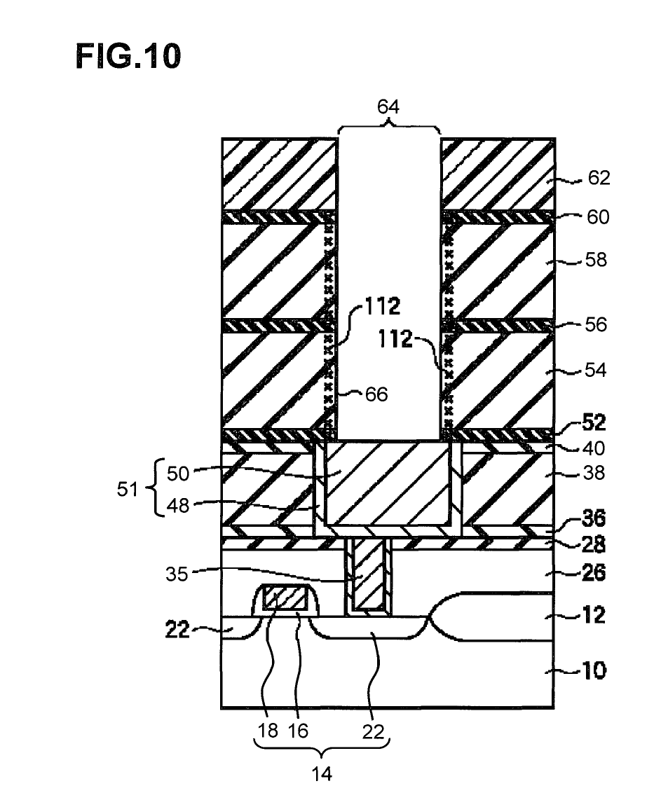

As shown in FIG. 10, the fifth insulating layer 60, the fifth interlayer insulating layer 58, the fourth insulating layer 56, the third interlayer insulating layer 54, and the third insulating layer 52 are sequentially dry-etched with, for example, an etching gas containing CF₄ and CHF₃ in such a manner that the second photoresist layer 62 is used as a mask, whereby via-holes 66 are formed so as to extend through the fifth insulating layer 60, the fifth interlayer insulating layer 58, the fourth insulating layer 56, the third interlayer insulating layer 54, and the third insulating layer 52 to the first wires 51. These insulating layers may be etched in such a manner that the composition and/or pressure of the etching gas is varied. In this dry etching step, the damaged layers 112, which contain the Si—OH groups, are also formed in the walls of the via-holes 66 as shown with crosses in FIG. 10.

The second photoresist layer 62 is removed by, for example, ashing. Even if wall deposits are formed on the walls of the via-holes 66 by dry etching during the formation of the via-holes 66, the wall deposits can be removed in this ashing step.

A third photoresist layer 68 is formed on the fifth insulating layer 60, which has the via-holes 66 therein. The third photoresist layer 68 has third openings 70 formed by photolithography. Through the third openings 70, regions for forming second wires 77b are exposed.

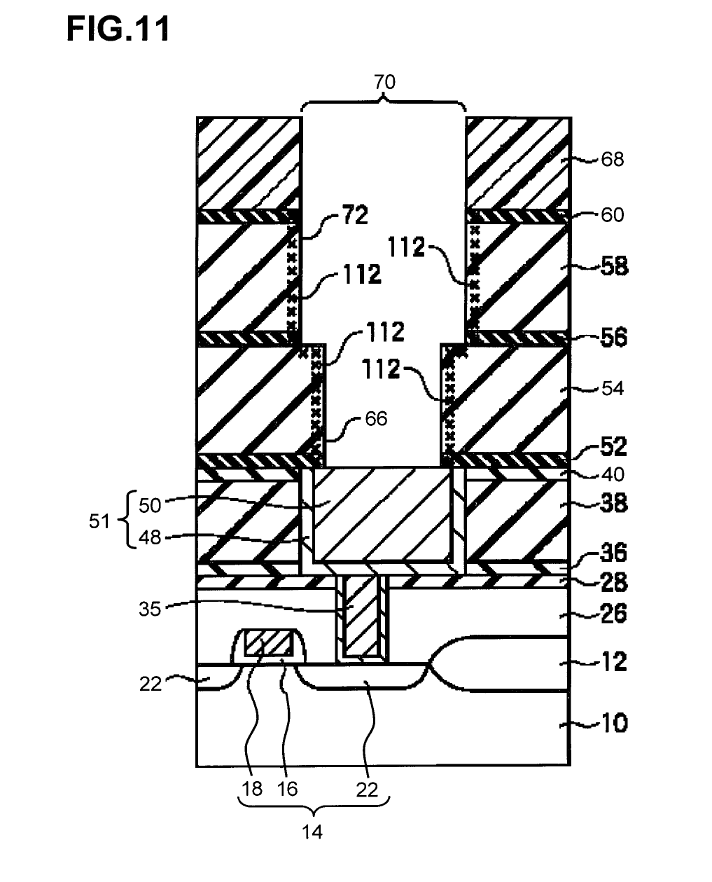

As shown in FIG. 11, the fifth insulating layer 60, the fifth interlayer insulating layer 58, and the fourth insulating layer 56 are sequentially dry-etched with, for example, a CF₄ gas and a CHF₃ gas in such a manner that the third photoresist layer 68 is used as a mask, whereby second wiring grooves 72 for forming the second wires 77b are formed. The second wires 77b extend through the fifth insulating layer 60, the fifth interlayer insulating layer 58, and the fourth insulating layer 56. The second wiring grooves 72 are connected to the via-holes 66. In this dry etching step, the damaged layers 112, which contain the Si—OH groups, are also formed in the walls of the second wiring grooves 72 as shown with crosses in FIG. 11.

The third photoresist layer 68 is removed by, for example, ashing. Even if wall deposits are formed on the walls of the second wiring grooves 72 by dry etching during the formation of the second wiring grooves 72, the wall deposits can be removed in this ashing step.

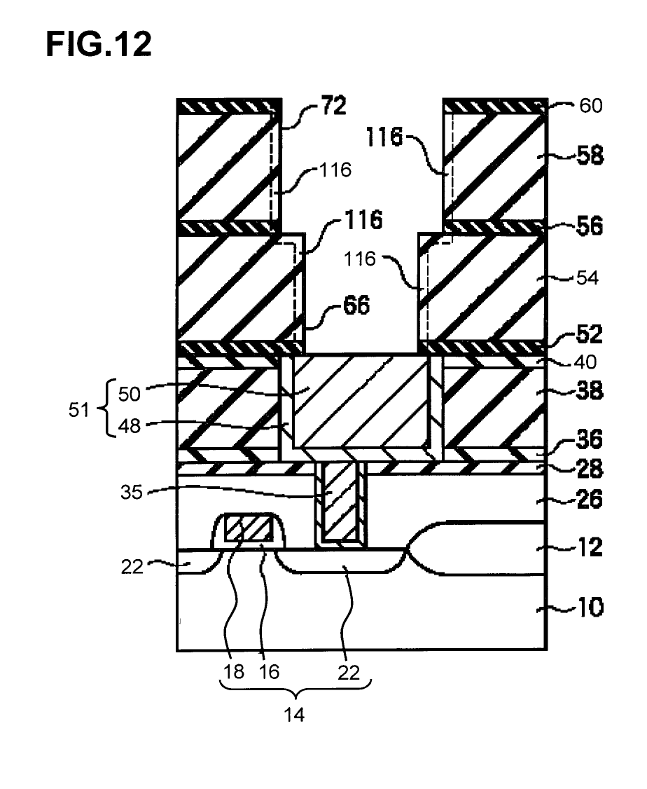

As shown in FIG. 12, after 3 cc of a silane compound, for example, hexamethyldisilazane is dripped onto the fifth insulating layer 60 and the fifth insulating layer 60 is then subjected to spin coating at 1,000 rpm for 60 seconds, the semiconductor substrate 10 is baked, for example, at 120° C. for 60 seconds and further baked at 250° C. for 60 seconds with a hot plate. This allows the Si—OH groups, which are produced by dry etching during the formation of the via-holes 66 and the second wiring grooves 72, to be converted into Si—CH₃ groups, whereby the damaged layers 112, which are present in the walls of the via-holes 66 and the second wiring grooves 72, are repaired. This also leads to the formation of the repaired layers 116.

The same silane compound and process used to repair the damaged layers 112 described in the first embodiment may be used in this step.

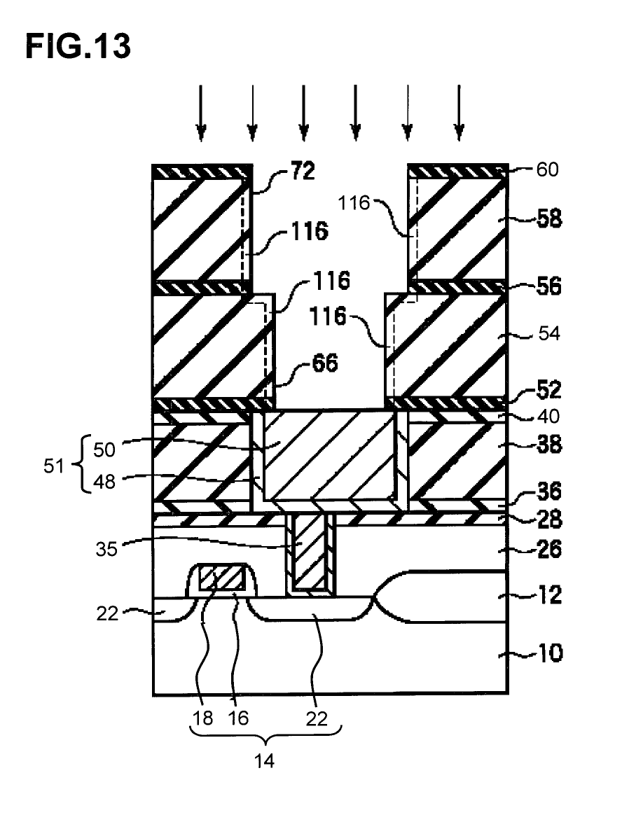

As shown in FIG. 13, the fifth insulating layer 60 is irradiated with ultraviolet rays having a wavelength of, for example, 200 to 600 nm for ten minutes using, for example, a UVL-7000 H4-N high-pressure mercury lamp available from Ushio Inc. in such a manner that the semiconductor substrate 10 is heat to, for example, 400° C. in a nitrogen atmosphere. This allows the remaining Si—OH groups to be converted into Si—O—Si groups by condensation, so that the adsorption of moisture by the remaining Si—OH groups is prevented.

The same process and conditions as those used to condense the Si—OH groups shown in the first embodiment may be used in this step. Electron beam irradiation may be performed in this step instead of light irradiation in the same manner as that shown in the first embodiment.

Tantalum nitride is deposited over the fifth insulating layer 60 by, for example, a sputtering process, whereby a third barrier metal layer 74 is formed. The third barrier metal layer 74 is tantalum nitride and has a thickness of, for example, 10 nm. The third barrier metal layer 74 prevents copper from diffusing from copper wires, formed in a subsequent step, into the insulating layers.

Copper is deposited on the third barrier metal layer 74 by, for example, a sputtering process, whereby a second seed layer (not shown) is formed. The second seed layer is made of copper and has a thickness of, for example, 10 nm.

A second copper coating is deposited on the second seed layer by, for example, an electroplating process, whereby a second copper layer 76 is formed. The second copper layer 76 includes the second seed layer and the second copper coating and has a thickness of, for example, 1,400 nm.

A portion of the second copper layer 76 that is located on the fifth insulating layer 60 and a portion of the third barrier metal layer 74 that is located above the fifth insulating layer 60 are removed by a CMP process, whereby second contact plugs 77a and the second wires 77b are co-formed so as to be connected to each other. The second contact plugs 77a include portions of the third barrier metal layer 74 that remain in the via-holes 66 and portions of the second copper layer 76 that remain therein. The second wires 77b include portions of the third barrier metal layer 74 that remain in the second wiring grooves 72 and portions of the second copper layer 76 that remain therein. A process for forming the second contact plugs 77a and the second wires 77b as described above is referred to as a dual damascene process.

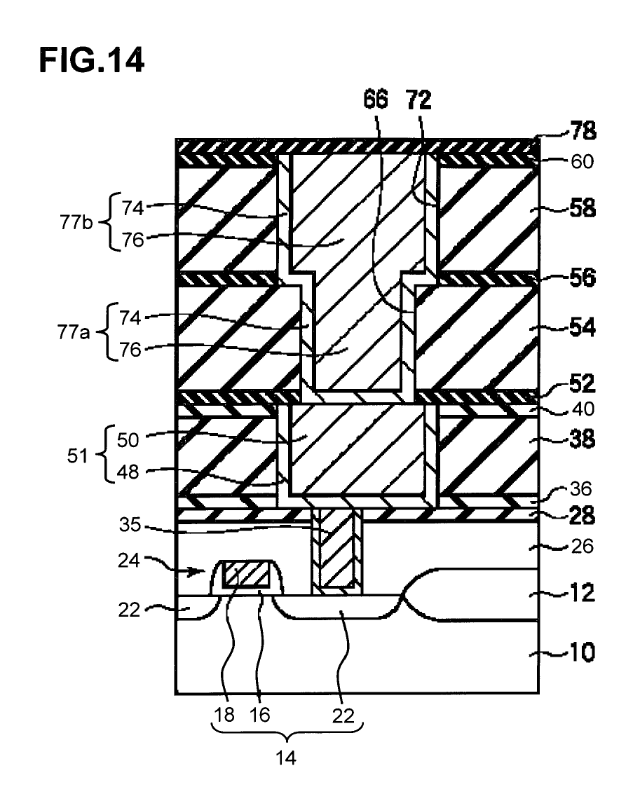

As shown in FIG. 14, SIC:O:H is deposited over the fifth insulating layer 60 by, for example, a CVD process, whereby a sixth insulating layer 78 is formed. The sixth insulating layer 78 is SiC:O:H and has a thickness of, for example, 30 nm. The sixth insulating layer 78 functions as a barrier layer for preventing the diffusion of moisture and the diffusion of copper from the second wires 77b.

Third wires and the like, which are not shown, are formed by repeating the same steps as the above as required, whereby the semiconductor device according to the present technique is completed.

According to this embodiment, the dielectric constant of the insulating layer can be prevented from being increased due to the damage caused by dry etching and also can be prevented from being increased by the exposure of the insulating layer to air. This allows the insulating layer to have a low dielectric constant and high reliability.

Hence, if the insulating layer is used as an interlayer insulating layer for multilayer wiring structures, a semiconductor device having a high response speed can be obtained.

### Third Embodiment

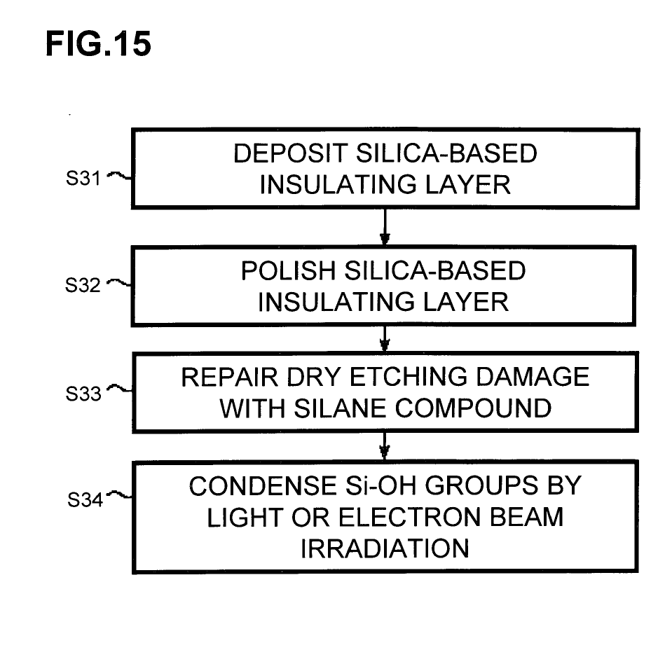

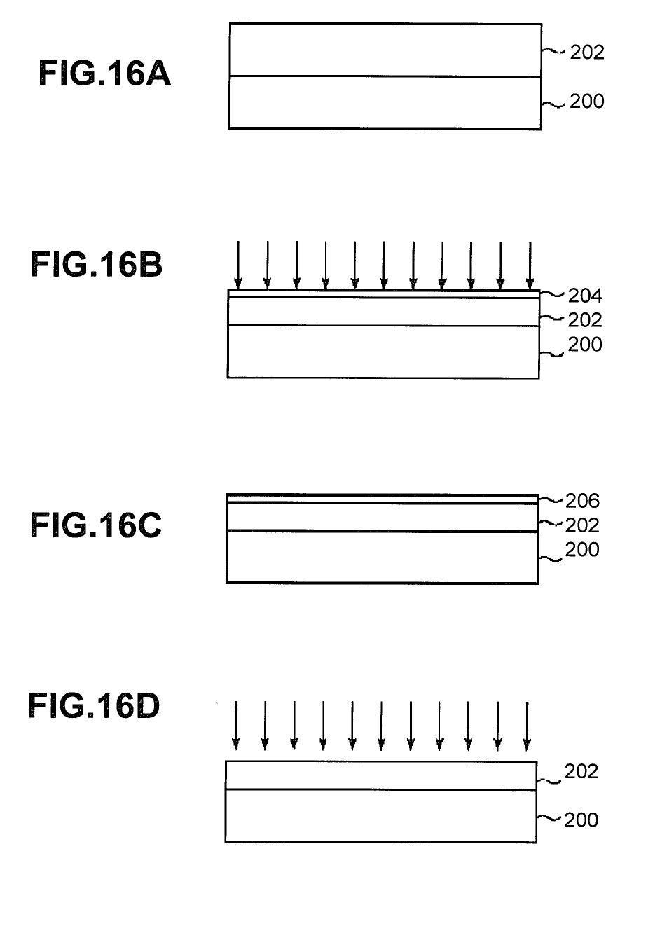

A method of manufacturing a semiconductor device according to a third embodiment will now be described with reference to FIGS. 15 and 16.

FIG. 15 is a flowchart illustrating the semiconductor device-manufacturing method of this embodiment. FIG. 16 is a sectional view showing steps of the semiconductor device-manufacturing method of this embodiment.

As shown in FIG. 1, the semiconductor device-manufacturing method of this embodiment includes a step (Step S31) of depositing a silica-based insulating layer, a step (Step S32) of polishing the silica-based insulating layer, a step (Step S33) of repairing the damage caused by dry etching using a silane compound, and a step (Step S34) of condensing Si—OH by light or electron beam irradiation.

The above steps are described below in detail with reference to FIG. 16.

The silica-based insulating layer 202 is formed on a base substrate 200 (Step S11 in FIG. 16A). Examples of the base substrate 200 include semiconductor substrates such as silicon substrates and semiconductor substrates including MIS transistors, one or more wiring layers, and other components.

The silica-based insulating layer 202 may be made of substantially the same material as that for forming the silica-based insulating layer 102 described in the first embodiment. The silica-based insulating layer 202 may be formed by substantially the same process as that used to form the silica-based insulating layer 102 described in the first embodiment.

A surface of the insulating layer 202 is polished by, for example, a chemical mechanical polishing (CMP) process such that the insulating layer 202 has a predetermined thickness. In this operation, a damaged layer having damage due to polishing is formed on the polished surface of the insulating layer 202 (FIG. 16B).

The term “damage due to polishing” means the damage caused by an acidic or alkaline chemical solution used for CMP. The damage, as well as that caused by dry etching described in the first and second embodiments, caused in the insulating layer by the acidic or alkaline chemical solution produces Si—OH bonds.

The damage caused by polishing the insulating layer 202 is repaired with the silane compound (Step S33). In this operation, the damaged layer 204 on the insulating layer 202 is repaired (a repaired layer 206 shown in FIG. 16C).

In particular, Si—OH produced by the damage caused by polishing is allowed to react with the silane compound. A process for allowing Si—OH to react with the silane compound is not particularly limited. Preferable examples of such a process include a spin-coating process and a vapor process in which treatment is performed at atmospheric pressure or in a vacuum using the silane compound. In particular, the vapor process is preferable because the vapor process is insensitive to surface tension.

In the vapor process, the substrate is preferably heated to a temperature of 50° C. to 350° C. such that the silane compound diffuses into the insulating layer 202 and a repaired portion is strengthened. In the spin-coating process, treatment is performed at atmospheric pressure with a spin coater and baking may be performed subsequently to spin coating such that the repaired portion is strengthened. In this case, baking is preferably performed at a single temperature or different temperatures within a range from 50° C. to 350° C.

The temperature of treatment is preferably determined within a range from 50° C. to 350° C. depending on the type of the silane compound. The upper limit of the treatment temperature depends on the boiling point of the silane compound and therefore is lower than or equal to the boiling point of the silane compound. The lower limit of the treatment temperature is 50° C., because the above damage cannot be sufficiently repaired with the silane compound.

The silane compound, which can be used to repair damage, is not particularly limited and may contain a functional group reactable with Si—OH produced by the damage caused by dry etching. Examples of the silane compound include silazane compounds such as dimethyldisilazane, tetramethyldisilazane, and hexamethyldisilazane; silylamide compounds such as bis(trimethylsilyl) acetamide and bis(triethylsilyl) acetamide; alkoxysilane compounds such as trimethoxysilane, triethoxysilane, methyltrimethoxysilane, methyltriethoxysilane, dimethylmethoxysilane, dimethylethoxysilane, trimethylmethoxysilane, trimethylethoxysilane, ethyltrimethoxysilane, ethyltriethoxysilane, diethylmethoxysilane, diethylethoxysilane, triethylmethoxysilane, triethylethoxysilane, propyltrimethoxysilane, propyltriethoxysilane, dipropylmethoxysilane, dipropylethoxysilane, tripropylimethoxysilane, tripropylethoxysilane, phenyltrimethoxysilane, phenyltriethoxysilane, diphenylmethoxysilane, diphenylethoxysilane, triphenylmethoxysilane, triphenylethoxysilane, phenylmethylmethoxysilane, phenylmethylethoxysilane, dimethylphenylmethoxysilane, dimethylphenylethoxysilane, diphenylmethylmethoxysilane, and diphenylmethylethoxysilane; and acetoxysilane compounds such as triacetoxysilane, triethoxysilane, methyltriethoxysilane, dimethylacetoxysilane, trimethylacetoxysilane, ethyltriacetoxysilane, diethylacetoxysilane, triethylacetoxysilane, dipropylacetoxysilane, tripropylacetoxysilane, phenyltriacetoxysilane, diphenylacetoxysilane, triphenylacetoxysilane, phenylmethylacetoxysilane, dimethylphenylacetoxysilane, and diphenylmethyltriacetoxysilane.

The repair of the damage allows Si—OH in the damaged layer 204 to be converted into Si—CH₃, resulting in an enhancement in hydrophobicity. The silane compound has a large molecular weight. This leads to steric hindrance; hence, it is difficult to entirely convert Si—OH into Si—CH₃. Therefore, if the damaged layer 204 is placed in air, Si—OH adsorbs moisture to cause an increase in dielectric constant.

Thus, according to the semiconductor device-manufacturing method of this embodiment, after the damage is repaired with the silane compound, remaining Si—OH is subjected to condensation (dehydrocondensation) such that Si—O—Si bonds are formed, whereby Si—OH is prevented from adsorbing moisture (Step S15). Si—OH can be condensed in such a manner that a layer is irradiated with light or an electron beam while the substrate is heated at 30° C. to 400° C. (FIG. 16D).

A light source used for condensation is not particularly limited and preferably emits light with a wavelength of 170 to 700 nm. Examples of the light source include excimer lamps, mercury lamps, and metal halide lamps. The temperature of the substrate irradiated with light is preferably 30° C. to 400° C.

An atmosphere preferably has an oxygen content of 150 ppm or less and may contain one or more of nitrogen, helium (He), and argon or may be a vacuum. In the case where irradiation is performed in a vacuum (at a reduced pressure), one or more of nitrogen, helium, and argon may be introduced into a vacuum chamber using a mass flow meter such that the vacuum chamber has a predetermined pressure.

In the condensation by electron beam irradiation, the damaged layer is preferably irradiated with an electron beam at an acceleration voltage of 1 to 15 kV in a vacuum. When the acceleration voltage is less than 1 kV, no sufficient effect can be achieved. When the acceleration voltage is greater than 15 kV, the insulating layer may be damaged.

The treatment temperature during light or electron beam irradiation is preferably within a range from 30° C. to 400° C. and may be selected depending on the type of the silica-based insulating layer. The upper limit of the treatment temperature depends on the upper temperature limit of the damaged layer, which forms an insulating layer, and is lower than the upper temperature limit of the damaged layer. The lower limit of the treatment temperature is 30° C., because condensation does not occur at a temperature lower than 30° C.

Since Si—OH is condensed subsequently to the repair of the damage with the silane compound as described above, the hygroscopicity of the insulating layer can be significantly reduced. This greatly reduces the amount of moisture adsorbed by the insulating layer even if the insulating layer is placed in air; hence, the dielectric constant of the insulating layer can be effectively prevented from being increased by the adsorption of moisture.

According to this embodiment, the damage caused in the insulating layer by polishing can be repaired and the dielectric constant of the insulating layer can be prevented from being increased even if the insulating layer is placed in air.

### Fourth Embodiment

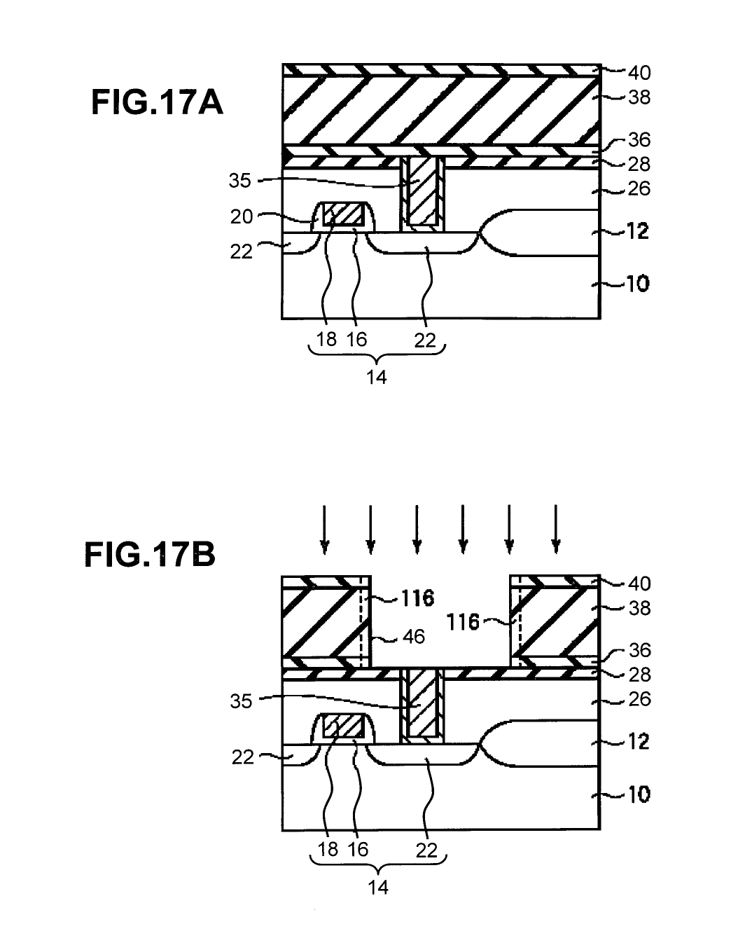

A method of manufacturing a semiconductor device according to a fourth embodiment will now be described with reference to FIGS. 17 to 21. The same components or members as those described in the semiconductor device-manufacturing method according to any one of the first to third embodiments with reference to FIGS. 1 to 16 are denoted by the same reference numerals as those used therein and will be simply described or will not be described.

FIGS. 17 to 21 are sectional views showing steps of the semiconductor device-manufacturing method of this embodiment.

In this embodiment, the following example is described: an example in which the manufacturing method according to the third embodiment is applied to the semiconductor device-manufacturing method according to the second embodiment.

The following components are formed on a semiconductor substrate 10 in substantially the same manner as that used in the semiconductor device-manufacturing method according to the second embodiment as shown in, for example, FIGS. 4A to 5B (FIG. 17A): an isolation layer 12, a MOS transistor 24, an interlayer insulating layer 26, a stopper layer, a contact plug 35, an insulating layer 36, an interlayer insulating layer 38, and an insulating layer 40.

A wiring groove 46 for forming a wiring 51 extending through the insulating layer 40, the interlayer insulating layer, and the insulating layer 36 is formed in substantially the same manner as that used in the semiconductor device-manufacturing method according to the second embodiment as shown in, for example, FIGS. 6A and 6B.

A damaged layer caused by dry etching during the formation of the wiring groove 46 is treated with a silane compound and irradiated with an ultraviolet ray in substantially the same manner as that used in the semiconductor device-manufacturing method according to the second embodiment as shown in, for example, FIGS. 7A and 7B, whereby the damaged layer is repaired (a repaired layer 116 shown in FIG. 17B).

A layer of titanium nitride (TaN) is deposited over the insulating layer 40 by, for example, a sputtering process so as to have a thickness of, for example, 50 nm, whereby a barrier metal layer 48 made of TaN is formed.

A layer of Cu is deposited on the barrier metal layer 48 by, for example, a sputtering process so as to have a thickness of, for example, 10 nm, whereby a seed sublayer (not shown) made of Cu is formed.

A Cu sublayer is deposited on the seed sublayer, which functions as a seed, by, for example, an electroplating process, whereby a Cu layer 50 including the seed sublayer is formed so as to have a thickness of, for example, 600 nm.

The Cu layer 50 and barrier metal layer 48 disposed on the insulating layer 40 are partly removed by a CMP process, whereby the wiring 51 is formed in the wiring groove 46. The wiring 51 includes a portion of the barrier metal layer 48 and a portion of the Cu layer 50. Slurry used for the CMP process is preferably selected depending on a material for forming the wiring 51 or the insulating layer 40. In this polishing step, a damaged layer containing Si—OH is formed in the insulating layer 40.

In the step of forming the wiring 51, an acidic or alkaline chemical solution used for polishing acts on the insulating layer 40 to produce Si—OH bonds in the insulating layer. The term “a step of causing a physical or chemical effect on the insulating layer” is hereinafter referred to as a step of processing the insulating layer. Examples of the step of processing the insulating layer include a step of patterning the insulating layer by dry etching or the like, a step of removing a conductive layer present on the insulating layer by polishing, and a step of partly removing the insulating layer by polishing.

Onto the insulating layer, 3 cc of a silane compound such as hexamethyldisilazane is dripped. The insulating layer is subjected to spin coating at 1000 rpm for 60 seconds; baked at, for example, 120° C. for 60 seconds on a hotplate; and then further baked at 250° C. for 60 seconds. This allows Si—OH, caused in the insulating layer 40 by polishing during the formation of the wiring 51, to be converted into Si—CH₃, thereby repairing the damage of the insulating layer 40.

The silane compound, which is used to repair the damage, and a treatment method using the silane compound may be the same as those used to repair the damaged layer 204 on the insulating layer 202 described in the semiconductor device-manufacturing method according to the third embodiment.

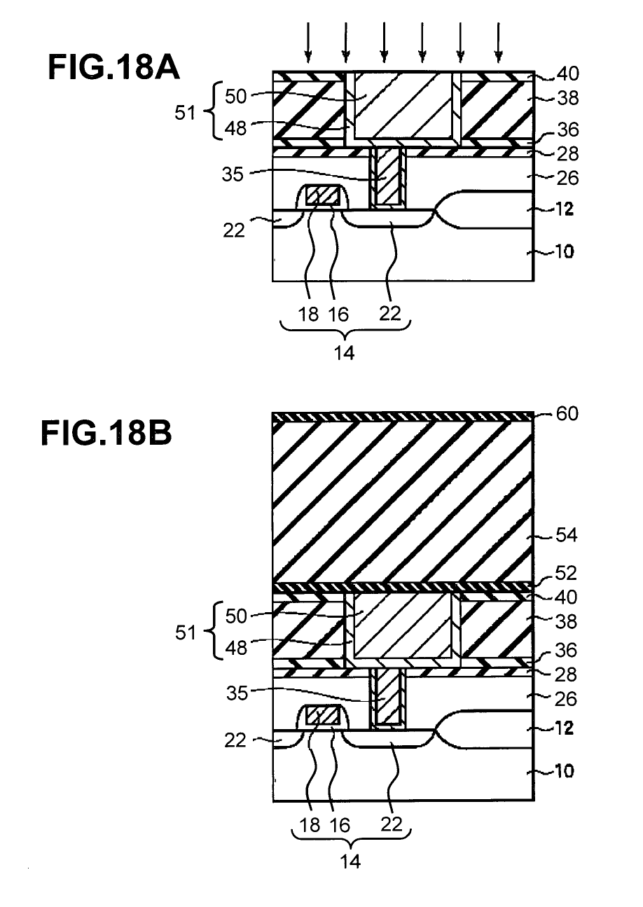

The insulating layer is irradiated with an ultraviolet ray with a wavelength of, for example, 200 to 600 nm for about ten minutes using a high-pressure mercury lamp (for example, UVL-7000 H4-N, available from Ushio Inc.) in such a manner that the substrate is heated at, for example, 400° C. in a nitrogen atmosphere (FIG. 18A). This allows Si—OH, which remains after the damage is repaired with the silane compound, to be condensed, so that Si—O—Si bonds are formed. Therefore, Si—OH can be prevented from adsorbing moisture.

The method and conditions described in the third embodiment can be used for light irradiation used for the condensation of Si—OH. Electron beam irradiation may be performed instead of light irradiation as described in the third embodiment. The method and conditions described in the third embodiment can be used for electron beam irradiation.

An insulating layer 52, an interlayer insulating layer 54, and an insulating layer 60 are formed on the insulating layer 40 having the wiring 51 embedded therein in substantially the same manner as that used in the semiconductor device-manufacturing method according to the second embodiment as shown in, for example, FIGS. 8A to 9 (FIG. 18B). In this embodiment, a three-layer structure consisting of the insulating layer 60, the interlayer insulating layer 54, and the insulating layer 52 is used. Instead, a structure including an insulating layer 56 serving as an etching stopper may be used as described in the second embodiment. In this embodiment, the interlayer insulating layer 54 may be a porous silica layer with a thickness of, for example, 180 nm.

The following hole and groove are formed in substantially the same manner as that used in the semiconductor device-manufacturing method according to the second embodiment as shown in, for example, FIGS. 10 and 11: a via-hole 66 extending through the insulating layer 52 and the interlayer insulating layer 54 to the wiring 51 and an wiring groove 72 for forming an wiring 77b extending through the interlayer insulating layer 54 and the insulating layer 60.

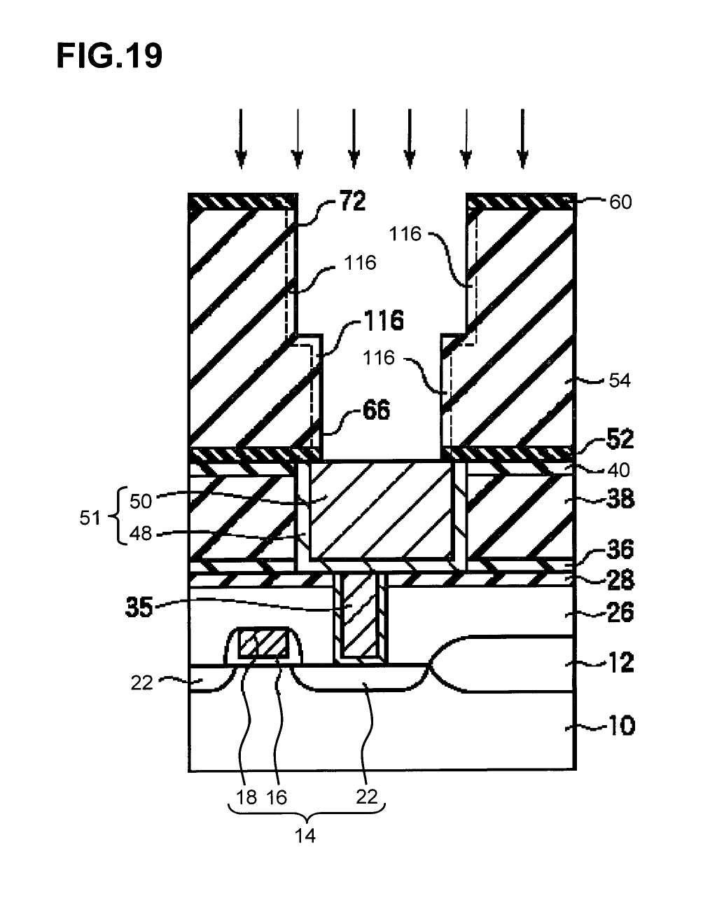

A damaged layer caused by dry etching during the formation of the via-hole 66 and the wiring groove 46 is treated with a silane compound and irradiated with an ultraviolet ray in substantially the same manner as that used in the semiconductor device-manufacturing method according to the second embodiment as shown in, for example, FIGS. 7A and 7B, whereby the damaged layer is repaired (a repaired layer 116 shown in FIG. 19).

A layer of TaN is deposited over the insulating layer 60 by, for example, a sputtering process so as to have a thickness of, for example, 10 nm, whereby a barrier metal layer 74 made of TaN is formed.

A layer of Cu is deposited on the barrier metal layer 74 by, for example, a sputtering process so as to have a thickness of, for example, 10 nm, whereby a seed sublayer (not shown) made of Cu is formed.

A Cu sublayer is deposited on the seed sublayer, which functions as a seed, by, for example, an electroplating process, whereby a Cu layer 76 including the seed sublayer is formed so as to have a thickness of, for example, 1400 nm.

The Cu layer 76 and barrier metal layer 74 disposed on the insulating layer 60 are partly removed by a CMP process, whereby a contact plug 77a and the wiring 77b are formed as one piece in one step. The contact plug 77a is disposed in the via-hole 66 and includes a portion of the barrier metal layer 74 and a portion of the Cu layer 76. The wiring 77b is disposed in the wiring groove 72 and includes a portion of the barrier metal layer 74 and a portion of the Cu layer 76. Slurry used for the CMP process is preferably selected depending on a material for forming the contact plug 77a and the wiring 77b or a material for forming the insulating layer 60. In this polishing step, a damaged layer containing Si—OH is formed in the insulating layer 60.

Onto the insulating layer, 3 cc of a silane compound such as hexamethyldisilazane is dripped. The insulating layer is subjected to spin coating at 1000 rpm for 60 seconds; baked at, for example, 120° C. for 60 seconds on a hotplate; and then further baked at 250° C. for 60 seconds. This allows Si—OH, caused in the insulating layer 60 by polishing during the formation of the contact plug 77a and the wiring 77b, to be converted into Si—CH₃, thereby repairing the damage of the insulating layer 60.

The silane compound, which is used to repair the damage, and a treatment method using the silane compound may be the same as those used to repair the damaged layer 204 on the insulating layer 202 described in the semiconductor device-manufacturing method according to the third embodiment.

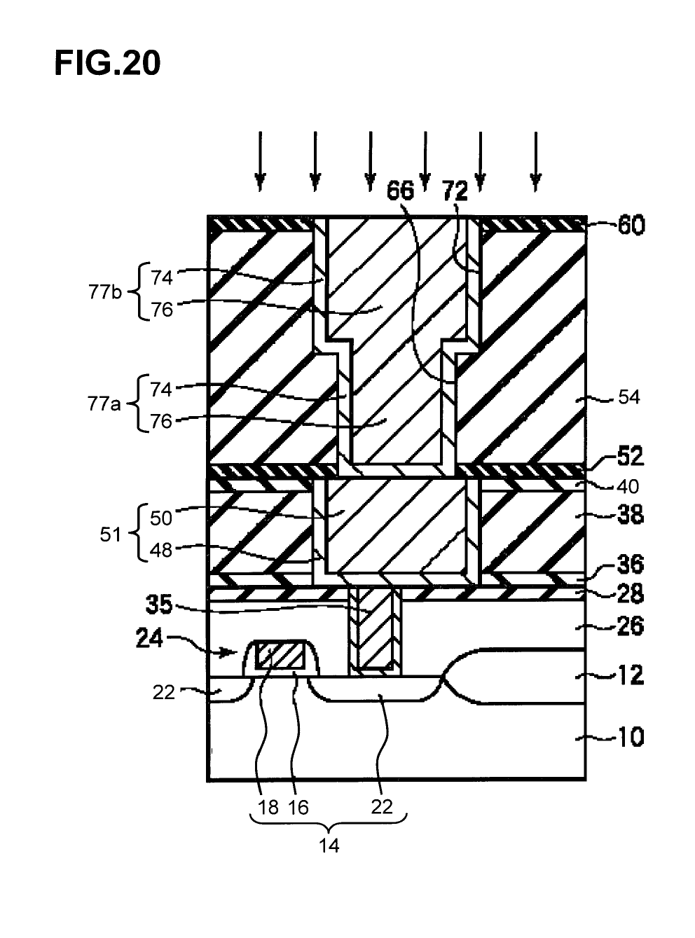

The insulating layer is irradiated with an ultraviolet ray with a wavelength of, for example, 200 to 600 nm for about ten minutes using a high-pressure mercury lamp (for example, UVL-7000 H4-N, available from Ushio Inc.) in such a manner that the substrate is heated at, for example, 400° C. in a nitrogen atmosphere (FIG. 20). This allows Si—OH, which remains after the damage is repaired with the silane compound, to be condensed, so that Si—O—Si bonds are formed. Therefore, Si—OH can be prevented from adsorbing moisture.

The method and conditions described in the third embodiment can be used for light irradiation used for the condensation of Si—OH. Electron beam irradiation may be performed instead of light irradiation as described in the third embodiment. The method and conditions described in the third embodiment can be used for electron beam irradiation.

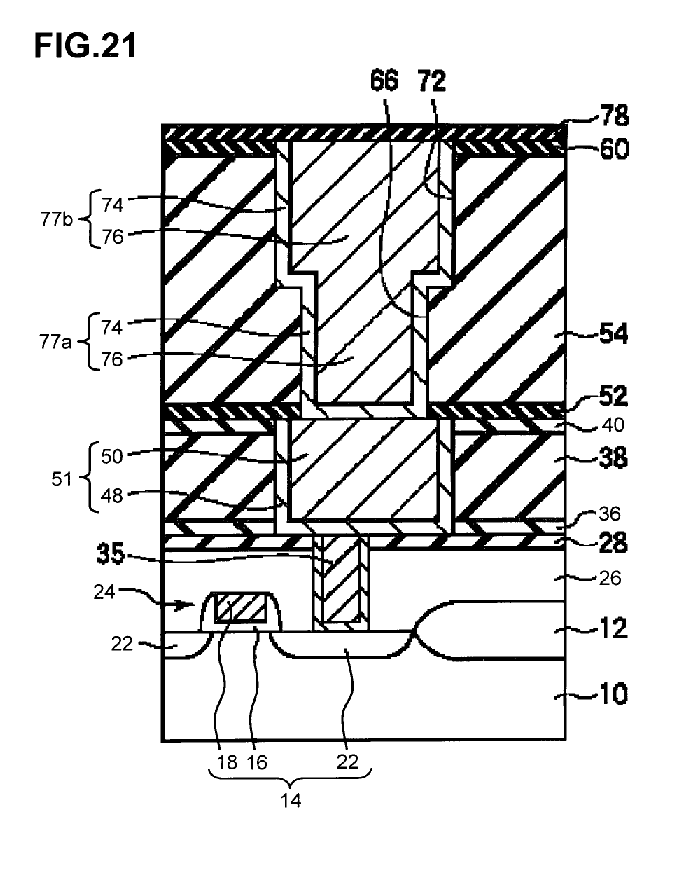

A layer of SiC:O:H is deposited over the interlayer insulating layer by, for example, a CVD process so as to have a thickness of about 30 nm, whereby an insulating layer 78 made of SiC:O:H is formed (FIG. 21).

The same steps as those described above are repeated as required such that a third wiring, which is not shown, and the like are formed, whereby the semiconductor device of this embodiment is completed.

As described above, according to this embodiment, the dielectric constants of the insulating layers are prevented from being increased in such a manner that the work damage of the insulating layers is repaired. Furthermore, the dielectric constants thereof can be prevented from being increased even if the insulating layers are placed in air.

This allows the insulating layers to have a low dielectric constant and high reliability. Therefore, the response speed of a semiconductor device can be increased if the insulating layers are applied to, for example, interlayer insulating layers for multi-level wiring structures.

### Fifth Embodiment

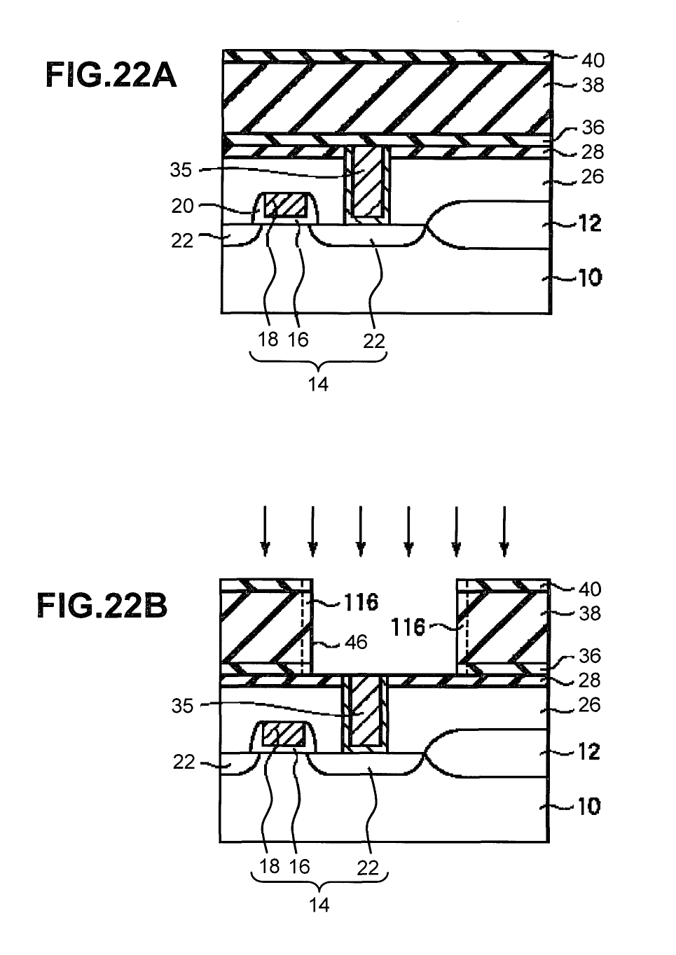

A method of manufacturing a semiconductor device according to a fifth embodiment will now be described with reference to FIGS. 22 to 26. The same components or members as those described in the semiconductor device-manufacturing method according to any one of the first to fourth embodiments with reference to FIGS. 1 to 21 are denoted by the same reference numerals as those used therein and will be simply described or will not be described.

FIGS. 22 to 26 are sectional views showing steps of the semiconductor device-manufacturing method of this embodiment.

In this embodiment, the following example is described: an example in which the manufacturing method according to the third embodiment is applied to the semiconductor device-manufacturing method according to the second embodiment.

The following components are formed on a semiconductor substrate 10 in substantially the same manner as that used in the semiconductor device-manufacturing method according to the second embodiment as shown in, for example, FIGS. 4A to 5B (FIG. 22A): an isolation layer 12, a MOS transistor 24, an interlayer insulating layer 26, a stopper layer, a contact plug 35, an insulating layer 36, an interlayer insulating layer 38, and an insulating layer 40.

A wiring groove 46 for forming a wiring 51 extending through the insulating layer 40, the interlayer insulating layer, and the insulating layer 36 is formed in substantially the same manner as that used in the semiconductor device-manufacturing method according to the second embodiment as shown in, for example, FIGS. 6A and 6B.

A damaged layer caused by dry etching during the formation of the wiring groove 46 is treated with a silane compound and irradiated with an ultraviolet ray in substantially the same manner as that used in the semiconductor device-manufacturing method according to the second embodiment as shown in, for example, FIGS. 7A and 7B, whereby the damaged layer is repaired (a repaired layer 116 shown in FIG. 22B).

A layer of tantalum nitride (TaN) is deposited over the insulating layer by, for example, a sputtering process so as to have a thickness of, for example, 10 nm, whereby a barrier metal layer 48 made of TaN is formed.

A layer of Cu is deposited on the barrier metal layer 48 by, for example, a sputtering process so as to have a thickness of, for example, 10 nm, whereby a seed sublayer (not shown) made of Cu is formed.

A Cu sublayer is deposited on the seed sublayer, which functions as a seed, by, for example, an electroplating process, whereby a Cu layer 50 including the seed sublayer is formed so as to have a thickness of, for example, 600 nm.

The Cu layer 50, barrier metal layer 48, and insulating layer 40 disposed on the interlayer insulating layer 38 are partly removed by a CMP process, whereby the wiring 51 is formed in the wiring groove 46. The wiring 51 includes a portion of the barrier metal layer 48 and a portion of the Cu layer 50.

In this embodiment, the insulating layer 40 is removed in a polishing step of forming the wiring 51. The insulating layer 40 is used as a hard mask for forming the wiring groove 46 and is usually made of a material having a dielectric constant greater than that of a material for forming the interlayer insulating layer 38. In this embodiment, in order to allow the interlayer insulating layer to have a low dielectric constant, the insulating layer 40 is removed in the polishing step of forming the wiring 51. Since the insulating layer 40 is removed by polishing, a damaged layer containing Si—OH is formed in the interlayer insulating layer 38 disposed under the insulating layer 40.

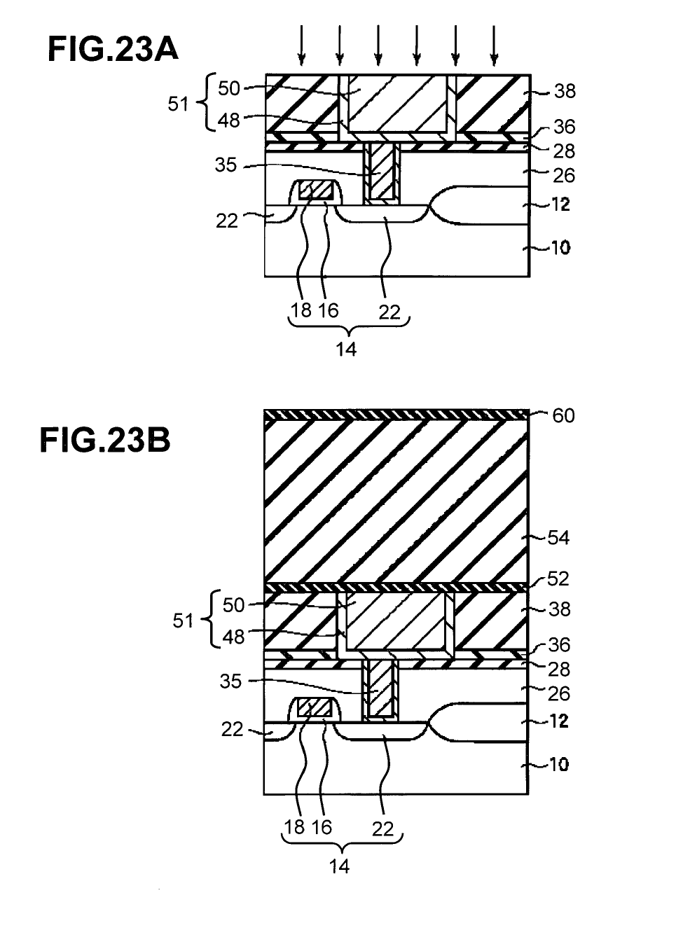

The damaged layer, which is formed in the interlayer insulating layer 38 by polishing during the formation of the wiring 51, is treated with a silane compound and irradiated with an ultraviolet ray in substantially the same manner as that used in the semiconductor device-manufacturing method according to the fourth embodiment as shown in, for example, FIG. 18B, whereby the damaged layer is repaired (FIG. 23A).

Since the insulating layer 40 is removed by polishing, the interlayer insulating layer 38 disposed thereunder is damaged and therefore the dielectric constant of the interlayer insulating layer 38 may be increased. However, since the damage of the interlayer insulating layer 38 is repaired by the above treatment, the dielectric constant of the interlayer insulating layer 38 can be prevented from being increased. The removal of the insulating layer 40 allows the interlayer insulating layer to have a lower dielectric constant.

An insulating layer 52, an interlayer insulating layer 54, and an insulating layer 60 are formed on the interlayer insulating layer 38 having the wiring 51 embedded therein in substantially the same manner as that used in the semiconductor device-manufacturing method according to the third embodiment as shown in, for example, FIG. 18A (FIG. 23B). In this embodiment, a three-layer structure consisting of the insulating layer 60, the interlayer insulating layer 54, and the insulating layer 52 is used. Instead, a structure including an insulating layer 56 serving as an etching stopper may be used as described in the second embodiment.

The following hole and groove are formed in substantially the same manner as that used in the semiconductor device-manufacturing method according to the second embodiment as shown in, for example, FIGS. 10 and 11: a via-hole 66 extending through the insulating layer 52 and the interlayer insulating layer 54 to the wiring 51 and an wiring groove 72 for forming an wiring 77b extending through the interlayer insulating layer 54 and the insulating layer 60.

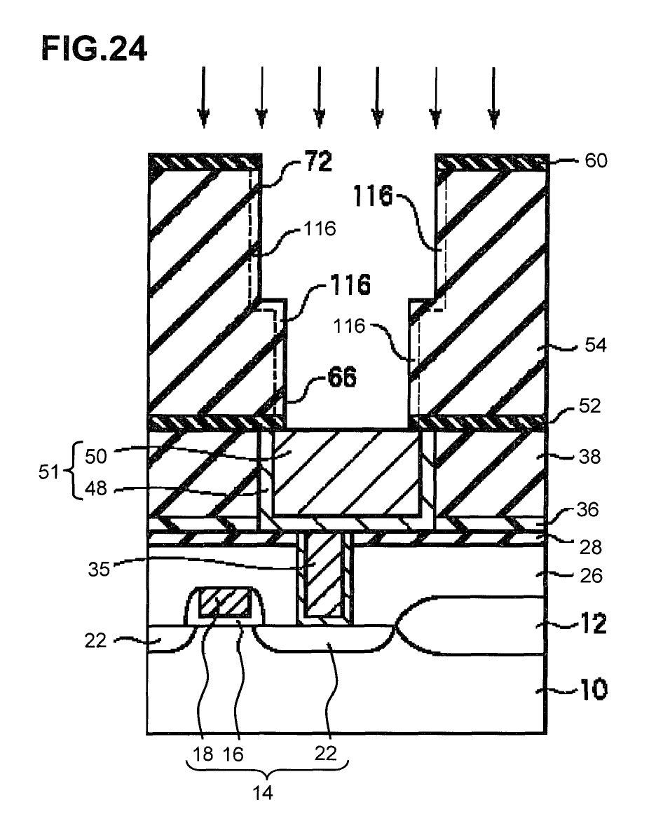

A damaged layer caused by dry etching during the formation of the via-hole 66 and the wiring groove 46 is treated with a silane compound and irradiated with an ultraviolet ray in substantially the same manner as that used in the semiconductor device-manufacturing method according to the second embodiment as shown in, for example, FIGS. 12 and 13, whereby the damaged layer is repaired (a repaired layer 116 shown in FIG. 24).

A layer of TaN is deposited over the insulating layer 60 by, for example, a sputtering process so as to have a thickness of, for example, 10 nm, whereby a barrier metal layer 74 made of TaN is formed.

A layer of Cu is deposited on the barrier metal layer 74 by, for example, a sputtering process so as to have a thickness of, for example, 10 nm, whereby a seed sublayer (not shown) made of Cu is formed.

A Cu sublayer is deposited on the seed sublayer, which functions as a seed, by, for example, an electroplating process, whereby a Cu layer 76 including the seed sublayer is formed so as to have a thickness of, for example, 1400 nm.

The Cu layer 76 and barrier metal layer 74 disposed on the insulating layer 60 are partly removed by a CMP process, whereby a contact plug 77a and the wiring 77b are formed as one piece in one step. The contact plug 77a is disposed in the via-hole 66 and includes a portion of the barrier metal layer 74 and a portion of the Cu layer 76. The wiring 77b is disposed in the wiring groove 72 and includes a portion of the barrier metal layer 74 and a portion of the Cu layer 76.

In this embodiment, the insulating layer 60 is removed in a polishing step of forming the contact plug 77a and the wiring 77b. The insulating layer 60 is used as a hard mask for forming the via-hole 66 and the wiring groove 46 and is usually made of a material having a dielectric constant greater than that of a material for forming the interlayer insulating layer 54. In this embodiment, in order to allow the interlayer insulating layer to have a low dielectric constant, the insulating layer 60 is removed in the polishing step of forming the contact plug 77a and the wiring 77b. Since the insulating layer 60 is removed by polishing, a damaged layer containing Si—OH is formed in the interlayer insulating layer 54 disposed under the insulating layer 60.

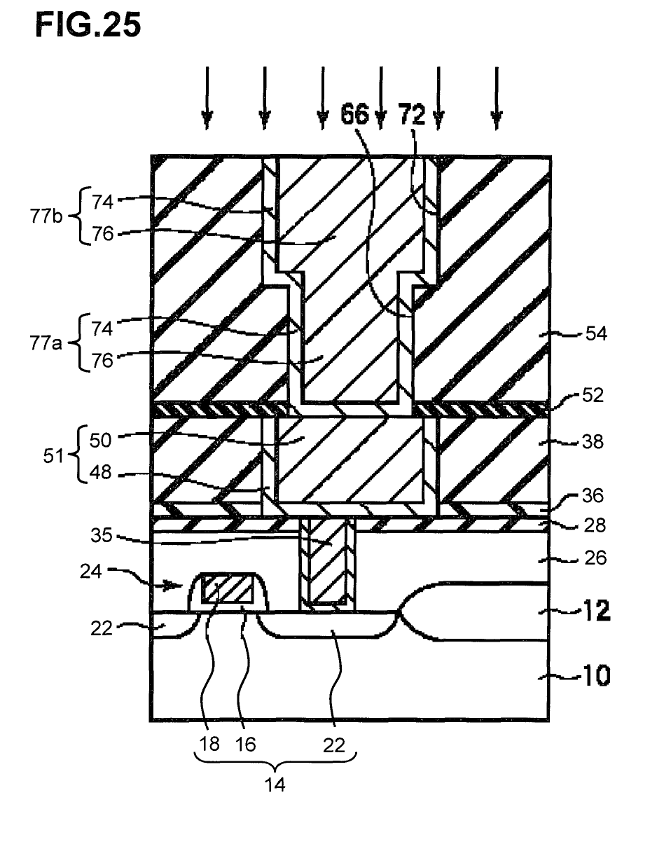

The damaged layer, which is formed in the interlayer insulating layer 54 by dry etching during the formation of the contact plug 77a and the wiring 77b, is treated with a silane compound and irradiated with an ultraviolet ray in substantially the same manner as that used in the semiconductor device-manufacturing method according to the fourth embodiment as shown in, for example, FIG. 19, whereby the damaged layer is repaired (FIG. 25).

Since the insulating layer 60 is removed by polishing, the interlayer insulating layer 54 disposed thereunder is damaged and therefore the dielectric constant of the interlayer insulating layer 54 may be increased. However, since the damage of the interlayer insulating layer 54 is repaired by the above treatment, the dielectric constant of the interlayer insulating layer 54 can be prevented from being increased. The removal of the insulating layer 60 allows the interlayer insulating layer to have a lower dielectric constant.

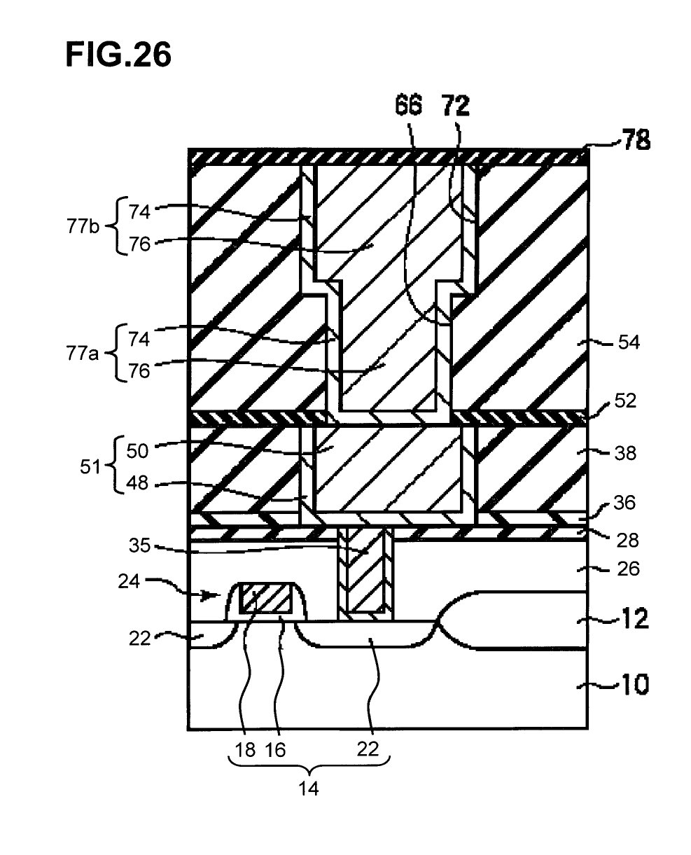

A layer of SiC:O:H is deposited over the interlayer insulating layer by, for example, a CVD process so as to have a thickness of about 30 nm, whereby an insulating layer 78 made of SiC:O:H is formed (FIG. 26).

The same steps as those described above are repeated as required such that a third wiring, which is not shown, and the like are formed, whereby the semiconductor device of this embodiment is completed.

As described above, according to this embodiment, the dielectric constants of the insulating layers are prevented from being increased in such a manner that the work damage of the insulating layers is repaired. Furthermore, the dielectric constants thereof can be prevented from being increased even if the insulating layers are placed in air. This allows the insulating layers to have a low dielectric constant and high reliability. Therefore, the response speed of a semiconductor device can be increased if the insulating layers are applied to, for example, interlayer insulating layers for multi-level wiring structures.

### Other Embodiments

The present technique is not limited to the semiconductor devices and methods of the first and second embodiments and can be widely applied to various semiconductor devices including silica-based insulating layers. The thickness of layers included in the semiconductor devices and materials for forming the layers may be varied within the scope of the present technique.

### EXAMPLES

### Example 1

The following compounds were charged into a 200-ml reaction vessel: 20.8 g (0.1 mol) of tetraethoxysilane, 17.8 g (0.1 mol) of methyltriethoxysilane, 23.6 g (0.1 mol) of glycidoxypropylsilane, and 39.6 g of methyl isobutyl ketone. Into the reaction vessel, 16.2 g (0.9 mol) of a 1% aqueous solution of tetramethylammonium hydroxide was dripped over ten minutes. The mixture in the reaction vessel was subjected to maturation reaction for two hours.

After an excessive amount of water was removed from the reaction mixture using 5 g of magnesium sulfate, ethanol produced by the maturation reaction was removed from the reaction mixture such that the volume of the reaction mixture was reduced to 50 ml. To the resulting reaction mixture, 20 ml of methyl isobutyl ketone was added, whereby a coating solution containing a porous silica precursor was prepared.

The porous silica precursor-containing coating solution was applied onto a low-resistance substrate by a spin-coating process. The low-resistance substrate was pre-baked at 250° C. for three minutes and then analyzed by FT-IR spectroscopy. The crosslinking degree of the coating of the low-resistance substrate was calculated to be 75% from the absorption intensity of Si—OH groups at about 950 cm⁻¹.

The porous silica precursor-containing coating solution was applied onto a silicon substrate 300 by a spin-coating process such that a layer of the porous silica precursor-containing coating solution had a thickness of about 400 nm.

The silicon substrate 300, which was coated with the porous silica precursor-containing coating solution, was pre-baked at 250° C. for three minutes.

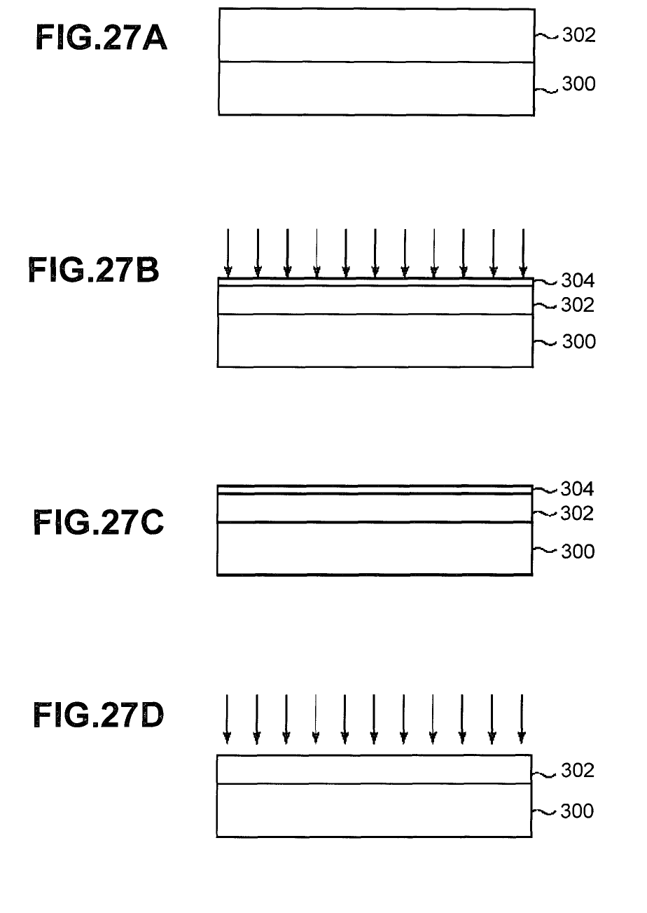

The porous silica precursor-containing coating solution layer on the pre-baked silicon substrate 300 was cured at 400° C. for 30 minutes in an electric furnace with a nitrogen atmosphere, whereby a silica-based porous insulating layer 302 was formed as shown in FIG. 27A.

The silica-based porous insulating layer 302 was dry-etched with a RIE etcher using a gas mixture of CHF₃ and CF₄ under the following conditions: a CHF₃ flow rate of 50 sccm, a CH₄ flow rate of 100 sccm, a chamber pressure of 50 mTorr, and a power of 200 W. This allowed the thickness of the silica-based porous insulating layer 302 to be reduced to about 200 nm and also allowed a damaged layer 304 to be formed thereon as shown in FIG. 27B.

Onto the damaged layer 304, 3 cc of hexamethyldisilazane was dripped. The damaged layer 304 was subjected to spin coating at 1,000 rpm for 60 seconds.

The silicon substrate 300 was baked at 120° C. for 60 seconds and further baked at 250° C. for 60 seconds with a hot plate, whereby the damaged layer 304 was prepared and therefore a repaired layer 306 was formed on the silica-based porous insulating layer 302 as shown in FIG. 27C.

As shown in FIG. 27D, the silica-based porous insulating layer 302 was irradiated with ultraviolet rays having a wavelength of 200 to 600 nm for ten minutes using a UVL-7000 H4-N high-pressure mercury lamp available from Ushio Inc. in such a manner that the silicon substrate 300 was heat to 400° C. in a nitrogen atmosphere.

The capacitance of the silica-based porous insulating layer 302 was measured with a mercury probe after each step and one-week exposure to air. The dielectric constant of the silica-based porous insulating layer 302 was calculated from the capacitance thereof. The calculation results were summarized in Table 1.

As shown in Table 1, the just-formed silica-based porous insulating layer 302 had a dielectric constant of 2.24. The dielectric constant thereof was increased by dry etching the silica-based porous insulating layer 302 because of the presence of the damaged layer 304, so that the dry-etched silica-based porous insulating layer 302 had a dielectric constant of 2.86. The dielectric constant of the dry-etched silica-based porous insulating layer 302 was reduced by treating the dry-etched silica-based porous insulating layer 302 with the silane compound but did not return to its initial value. The treated silica-based porous insulating layer 302 had a dielectric constant of 2.36. The dielectric constant of the treated silica-based porous insulating layer 302 was further reduced by irradiating the dry-etched silica-based porous insulating layer 302 with the ultraviolet rays, so that the irradiated silica-based porous insulating layer 302 had a dielectric constant of 2.26. The silica-based porous insulating layer 302 exposed to air for one week had a dielectric constant of 2.25.

### Example 2

An evaluation sample was prepared in substantially the same manner as that described in Example 1 except that electron beam irradiation was performed instead of the irradiation with the ultraviolet rays as shown in FIG. 27D. In the preparation of the evaluation sample, a dry-etched silica-based porous insulating layer was irradiated with an electron beam having an acceleration voltage of 10 kV for one minute in such a manner that a silicon substrate was heated to 400° C. in a vacuum.

The capacitance of the silica-based porous insulating layer was measured with a mercury probe after each step and one-week exposure to air. The dielectric constant of the silica-based porous insulating layer was calculated from the capacitance thereof. The calculation results were summarized in Table 1.

As shown in Table 1, the just-formed silica-based porous insulating layer had a dielectric constant of 2.24. The dielectric constant thereof was increased by dry etching the silica-based porous insulating layer because of the presence of a damaged layer, so that the dry-etched silica-based porous insulating layer had a dielectric constant of 2.86. The dielectric constant of the dry-etched silica-based porous insulating layer was reduced by treating the dry-etched silica-based porous insulating layer with the silane compound but did not return to its initial value. The treated silica-based porous insulating layer 202 had a dielectric constant of 2.36. The dielectric constant of the treated silica-based porous insulating layer was further reduced by irradiating the dry-etched silica-based porous insulating layer with the electron beam, so that the irradiated silica-based porous insulating layer had a dielectric constant of 2.28. The silica-based porous insulating layer exposed to air for one week had a dielectric constant of 2.26.

### Comparative Example 1

An evaluation sample was prepared in substantially the same manner as that described in Example 1 or 2 except that no ultraviolet ray or electron beam irradiation was performed as shown in FIG. 27D.

The capacitance of a silica-based porous insulating layer of the evaluation sample was measured with a mercury probe after each step and one-week exposure to air. The dielectric constant of the silica-based porous insulating layer was calculated from the capacitance thereof. The calculation results were summarized in Table 1.

As shown in Table 1, the just-formed silica-based porous insulating layer had a dielectric constant of 2.24. The dielectric constant thereof was increased by dry etching the silica-based porous insulating layer because of the presence of a damaged layer, so that the dry-etched silica-based porous insulating layer had a dielectric constant of 2.86. The dielectric constant of the dry-etched silica-based porous insulating layer was reduced by treating the dry-etched silica-based porous insulating layer with the silane compound but did not return to its initial value. The treated silica-based porous insulating layer 202 had a dielectric constant of 2.36.

The treated silica-based porous insulating layer was exposed to air for one week without subjecting the treated silica-based porous insulating layer to ultraviolet ray or electron beam irradiation. The resulting silica-based porous insulating layer had a dielectric constant of 2.52.

TABLE 1

| | DIELECTRIC CONSTANT | | |
|---|---|---|---|
| | EXAM- | EXAM- | COMPARATIVE |
| PROCESS | PLE 1 | PLE 2 | EXAMPLE 1 |
| JUST-FORMED SILICA- | 2.24 | 2.24 | 2.24 |
| BASED POROUS | | | |
| INSULATING LAYER | | | |
| JUST-DRY-ETCHED | 2.86 | 2.86 | 2.86 |
| JUST-TREATED WITH | 2.36 | 2.36 | 2.36 |
| SILANE COMPOUND | | | |
| JUST-IRRADIATED WITH | 2.26 | — | — |
| ULTRAVIOLET RAYS | | | |
| JUST-IRRADIATED WITH | — | 2.28 | — |
| ELECTRON BEAM | | | |
| AFTER EXPOSED TO AIR | 2.25 | 2.26 | 2.52 |
| FOR ONE WEEK | | | |

### Example 3

A semiconductor device was manufactured by the method according to the second embodiment. In particular, second and third wires of the semiconductor device were formed under the same process conditions.

The yield of one million via-holes was measured using multilayer wires of the semiconductor device, so that the yield thereof was determined to be 91%. The effective dielectric constant of an interlayer insulating layer was determined to be 2.60 from the interlayer capacitance. After the semiconductor device was subjected to high-temperature storage at 200° C. for 1,000 hours, the semiconductor device was measured for wiring resistance. The measurement results showed no increase in the wiring resistance thereof.

### Example 4

A semiconductor device was manufactured by substantially the same method as that described in Example 3 except that ultraviolet ray irradiation was performed in a helium atmosphere after the repair of damage with the silane compound. In particular, an insulating layer of which the damage was repaired was irradiated with ultraviolet rays having a wavelength of 200 to 600 nm for ten minutes using a UVL-7000 H4-N high-pressure mercury lamp available from Ushio Inc. in such a manner that a substrate was heat to 400° C. in the helium atmosphere.

The yield of one million via-holes was measured using multilayer wires of the semiconductor device, so that the yield thereof was determined to be 94%. The effective dielectric constant of an interlayer insulating layer was determined to be 2.58 from the interlayer capacitance. After the semiconductor device was subjected to high-temperature storage at 200° C. for 1,000 hours, the semiconductor device was measured for wiring resistance. The measurement results showed no increase in the wiring resistance thereof.

### Example 5

A semiconductor device was manufactured by substantially the same method as that described in Example 3 except that ultraviolet ray irradiation was performed in an argon atmosphere after the repair of damage with the silane compound. In particular, an insulating layer of which the damage was repaired was irradiated with ultraviolet rays having a wavelength of 200 to 600 nm for ten minutes using a UVL-7000 H4-N high-pressure mercury lamp available from Ushio Inc. in such a manner that a substrate was heat to 400° C. in the argon atmosphere.

The yield of one million via-holes was measured using multilayer wires of the semiconductor device, so that the yield thereof was determined to be 93%. The effective dielectric constant of an interlayer insulating layer was determined to be 2.61 from the interlayer capacitance. After the semiconductor device was subjected to high-temperature storage at 200° C. for 1,000 hours, the semiconductor device was measured for wiring resistance. The measurement results showed no increase in the wiring resistance thereof.

### Example 6

A semiconductor device was manufactured by substantially the same method as that described in Example 3 except that ultraviolet ray irradiation was performed in a vacuum after the repair of damage with the silane compound. In particular, an insulating layer of which the damage was repaired was irradiated with ultraviolet rays having a wavelength of 200 to 600 nm for ten minutes using a UVL-7000 H4-N high-pressure mercury lamp available from Ushio Inc. in such a manner that a substrate was heat to 400° C. in the argon atmosphere.

The yield of one million via-holes was measured using multilayer wires of the semiconductor device, so that the yield thereof was determined to be 96%. The effective dielectric constant of an interlayer insulating layer was determined to be 2.52 from the interlayer capacitance. After the semiconductor device was subjected to high-temperature storage at 200° C. for 1,000 hours, the semiconductor device was measured for wiring resistance. The measurement results showed no increase in the wiring resistance thereof.

### Example 7

A semiconductor device was manufactured by substantially the same method as that described in Example 3 except that electron beam irradiation was performed instead of ultraviolet ray irradiation after the repair of damage with the silane compound. In particular, an insulating layer was irradiated with an electron beam having an acceleration voltage of 10 kV for one minute in such a manner that a substrate was heat to 400° C. in a vacuum.

The yield of one million via-holes was measured using multilayer wires of the semiconductor device, so that the yield thereof was determined to be 90%. The effective dielectric constant of an interlayer insulating layer was determined to be 2.63 from the interlayer capacitance. After the semiconductor device was subjected to high-temperature storage at 200° C. for 1,000 hours, the semiconductor device was measured for wiring resistance. The measurement results showed no increase in the wiring resistance thereof.

### Comparative Example 2

A semiconductor device was manufactured by substantially the same method as that described in Example 3 except that none of the repair of damage with any silane compound, light irradiation, and electron beam irradiation was performed.

The yield of one million via-holes was measured using multilayer wires of the semiconductor device, so that the yield thereof was determined to be 72%. The effective dielectric constant of an interlayer insulating layer was determined to be 2.96 from the interlayer capacitance. After the semiconductor device was subjected to high-temperature storage at 200° C. for 1,000 hours, the semiconductor device was measured for wiring resistance. The measurement results showed that 45% of the via-holes were increased in wiring resistance.

### Comparative Example 3

A semiconductor device was manufactured in such a manner that damage was repaired with a silane compound by the process described in Example 3 without performing light or electron beam irradiation.

One million continuous via-holes were measured for yield using multi-level wirings in the semiconductor device. This showed that the yield of the via-holes was 81%. The effective dielectric constant of an interlayer insulating layer was determined to be 2.82 from interlayer capacitance. The semiconductor device was left at 200° C. for 1000 hours and then measured for wiring resistance. This showed that 18% of the via-holes were increased in resistance.

### Example 8

The following compounds were fed into a 200-ml reaction vessel: 20.8 g (0.1 mol) of tetraethoxysilane, 17.8 g (0.1 mol) of methyltriethoxysilane, 23.6 g (0.1 mol) of glycidoxypropyltrimethoxysilane, and 39.6 g of methyl isobutyl ketone. Into the reaction vessel, 16.2 g (0.9 mol) of a 1% aqueous solution of tetramethylammonium hydroxide was dripped over ten minutes. After the completion of dripping, aging was performed for two hours.

After an excessive amount of water was removed from the reaction liquid using 5 g of magnesium sulfate, ethanol produced by aging was removed from the reaction liquid in a rotary evaporator such that the volume of the reaction liquid was reduced to 50 ml. To the concentrated reaction liquid, 20 ml of methyl isobutyl ketone was added, whereby a porous silica precursor coating solution for forming a wiring isolation layer is prepared.

The porous silica precursor coating solution was applied onto a low-resistance substrate by spin coating and then pre-baked at 250° C. for three minutes. The degree of crosslinking of the porous silica precursor coating solution was determined to be 75% by FT-IR from an absorption peak, centered at 950 cm⁻¹, corresponding to Si—OH.

A layer of the porous silica precursor coating solution was formed on a base substrate 200 made of silicon by a spin coating process so as to have a thickness of 400 nm.

The porous silica precursor coating solution layer disposed on the base substrate 200 was pre-baked at 250° C. for three minutes.

The pre-baked porous silica precursor coating solution layer was cured at 400° C. for 30 minutes in an electric furnace with a nitrogen atmosphere, whereby a silica-based porous insulating layer 202 was formed (see FIG. 16A).

The silica-based porous insulating layer 202 was polished with a chemical mechanical polishing (CMP) apparatus. This allowed the thickness of the silica-based porous insulating layer 202 to be reduced and caused a damaged layer 204 to be formed thereon (see FIG. 16B).

The polished silica-based porous insulating layer 202 was cleaned with a 0.5% aqueous solution of hydrofluoric acid.

Onto the polished silica-based porous insulating layer 202, 3 cc of hexamethyldisilazane was dripped. The silica-based porous insulating layer 202 was subjected to spin coating at 1000 rpm for 60 seconds.

The silica-based porous insulating layer 202 was baked at 120° C. for 60 seconds on a hotplate and then further baked at 250° C. for 60 seconds. This allowed the damaged layer 204 to be repaired, whereby a repaired layer 206 was formed on the silica-based porous insulating layer 202 (see FIG. 16C).

The silica-based porous insulating layer was irradiated with an ultraviolet ray with a wavelength of 200 to 600 nm for ten minutes using a high-pressure mercury lamp (UVL-7000 H4-N, available from Ushio Inc.) in such a manner that the substrate was heated at 400° C. in a nitrogen atmosphere (FIG. 15D).

Table 2 summarizes the dielectric constant of the silica-based porous insulating layer 202 processed in each step or left in air for one week, the dielectric constant being calculated from the capacitance determined with a mercury prober.

As shown in Table 2, the silica-based porous insulating layer 202 just formed has a dielectric constant of 2.24. The polish of this layer causes the formation of the damaged layer 204 to increase the dielectric constant thereof to 3.12. The repair of the damaged layer with the silane compound allows the dielectric constant thereof to be reduced to 2.39; however, the dielectric constant thereof does not return to its original value. The silica-based porous insulating layer 202 treated with the silane compound and then irradiated with the ultraviolet ray has a dielectric constant of 2.25, which is close to its original value. The silica-based porous insulating layer 202 left in air for one week has a dielectric constant of 2.25.

### Example 9

An evaluation sample was prepared in substantially the same manner as that described in Example 8 except that electron beam irradiation was performed in a step shown in FIG. 16D instead of light irradiation. In particular, a silica-based porous insulating layer was irradiated with an electron beam at an acceleration voltage of 10 kV for one minute in such a manner that a substrate was heated to 400° C. in a vacuum.

Table 2 summarizes the dielectric constant of the silica-based porous insulating layer processed in each step or left in air for one week, the dielectric constant being calculated from the capacitance determined with a mercury prober.

As shown in Table 2, the silica-based porous insulating layer 202 just formed has a dielectric constant of 2.24. The polish of this layer causes the formation of a damaged layer 204 to increase the dielectric constant thereof to 3.12. The repair of the damaged layer with the silane compound allows the dielectric constant thereof to be reduced to 2.39; however, the dielectric constant thereof does not return to its original value. The silica-based porous insulating layer 202 treated with the silane compound and then irradiated with an ultraviolet ray has a dielectric constant of 2.25, which is close to its original value. The silica-based porous insulating layer 202 left in air for one week has a dielectric constant of 2.26.

### Comparative Example 4

An evaluation sample was prepared in substantially the same manner as that described in Example 1 or 2 except that no light or electron beam irradiation was performed in the step shown in FIG. 16D.

Table 2 summarizes the dielectric constant of a silica-based porous insulating layer processed in each step or left in air for one week, the dielectric constant being calculated from the capacitance determined with a mercury prober.

As shown in Table 2, the silica-based porous insulating layer just formed has a dielectric constant of 2.24. The polish of this layer causes the formation of a damaged layer 204 to increase the dielectric constant thereof to 3.12. The repair of the damaged layer with the silane compound allows the dielectric constant thereof to be reduced to 2.39; however, the dielectric constant thereof does not return to its original value. The silica-based porous insulating layer irradiated with no light or ultraviolet ray and left in air for one week has a dielectric constant of 2.55.

TABLE 2

| | DIELECTRIC CONSTANT | | |
|---|---|---|---|
| | EXAM- | EXAM- | COMPARATIVE |
| PROCESS | PLE 8 | PLE 9 | EXAMPLE 4 |
| JUST-FORMED SILICA- | 2.24 | 2.24 | 2.24 |
| BASED POROUS | | | |
| INSULATING LAYER | | | |
| JUST-POLISHED | 3.12 | 3.12 | 3.12 |
| JUST-TREATED WITH | 2.39 | 2.39 | 2.39 |
| SILANE COMPOUND | | | |
| JUST-IRRADIATED WITH | 2.25 | — | — |
| ULTRAVIOLET RAYS | | | |
| JUST-IRRADIATED WITH | — | 2.25 | — |
| ELECTRON BEAM | | | |
| AFTER EXPOSED TO AIR | 2.25 | 2.26 | 2.55 |
| FOR ONE WEEK | | | |

### Example 10

Evaluation samples were prepared in substantially the same manner as that described in Example 8 except that the temperature of heat treatment was varied during light irradiation in the step shown in FIG. 16D. In particular, the evaluation samples were irradiated with light in such a manner that the evaluation samples were each heated at 30° C., 60° C., 100° C., 150° C., 200° C., 250° C., 300° C., 350° C., or 400° C.

Table 3 summarizes the dielectric constants of silica-based porous insulating layers of the evaluation samples just formed or left in air for one week, the dielectric constants being calculated from the capacitance determined with a mercury prober.

As shown in Table 3, the silica-based porous insulating layers 202 of the evaluation samples just formed have a dielectric constant of 2.24 to 2.26. The silica-based porous insulating layers 202 left in air for one week, as well as those just formed, have a low dielectric constant of 2.24 to 2.26.

### Example 11

Evaluation samples were prepared in substantially the same manner as that described in Example 9 except that the temperature of heat treatment was varied during electron beam irradiation in the step shown in FIG. 16D. In particular, the evaluation samples were irradiated with light in such a manner that the evaluation samples were each heated at 30° C., 60° C., 100° C., 150° C., 200° C., 250° C., 300° C., 350° C., or 400° C.

Table 3 summarizes the dielectric constants of silica-based porous insulating layers of the evaluation samples just formed or left in air for one week, the dielectric constants being calculated from the capacitance determined with a mercury prober.

As shown in Table 3, the silica-based porous insulating layers 202 of the evaluation samples just formed have a dielectric constant of 2.24 to 2.26. The silica-based porous insulating layers 202 left in air for one week, as well as those just formed, have a small dielectric constant of 2.24 to 2.26.

### Comparative Example 5

Evaluation samples were prepared in substantially the same manner as that described in Example 10 or 11 except that no light or electron beam irradiation was performed in the step shown in FIG. 16D.

Table 3 summarizes the dielectric constants of silica-based porous insulating layers of the evaluation samples just formed or left in air for one week, the dielectric constants being calculated from the capacitance determined with a mercury prober.

As shown in Table 3, the silica-based porous insulating layers 202 of the evaluation samples just formed have a dielectric constant of 2.34 to 2.39. That is, the dielectric constants of the silica-based porous insulating layers 202 of the evaluation samples just formed are greater than those described in Example 10 or 11, in which light or electron beam irradiation was performed. The silica-based porous insulating layers 202 left in air for one week have a large dielectric constant of 2.52 to 2.56.

### Example 12

A third wiring layer and other members were formed by the semiconductor device-manufacturing method according to the fourth embodiment. After damage was repaired with a silane compound subsequently to dry etching and polishing, ultraviolet ray irradiation was performed in a nitrogen atmosphere. The third wiring layer was formed under substantially the same process conditions as those for forming a second wiring layer.

One million continuous via-holes were measured for yield using multi-level wirings in a semiconductor device manufactured as described above. This showed that the yield of the via-holes was 91%. The effective dielectric constant of an interlayer insulating layer was determined to be 2.60 from interlayer capacitance. The semiconductor device was left at 200° C. for 1000 hours and then measured for wiring resistance. This showed that the resistance thereof was not increased.

TABLE 3

| | DIELECTRIC CONSTANT | | | | | |
|---|---|---|---|---|---|---|
| HEAT | EXAMPLE 10 | | EXAMPLE 11 | | COMPARATIVE EXAMPLE 5 | |
| TREATMENT | | LEFT IN | | LEFT IN | | LEFT IN |
| TEMPERATURE | JUST | AIR FOR | JUST | AIR FOR | JUST | AIR FOR |
| [° C.] | FORMED | ONE WEEK | FORMED | ONE WEEK | FORMED | ONE WEEK |
| 30 | 2.26 | 2.26 | 2.25 | 2.25 | 2.39 | 2.55 |
| 60 | 2.26 | 2.26 | 2.25 | 2.25 | 2.38 | 2.54 |
| 100 | 2.25 | 2.25 | 2.24 | 2.26 | 2.38 | 2.56 |
| 150 | 2.26 | 2.25 | 2.26 | 2.25 | 2.36 | 2.55 |
| 200 | 2.25 | 2.26 | 2.25 | 2.26 | 2.37 | 2.55 |
| 250 | 2.26 | 2.24 | 2.25 | 2.25 | 2.35 | 2.53 |
| 300 | 2.24 | 2.26 | 2.25 | 2.24 | 2.35 | 2.52 |
| 350 | 2.25 | 2.25 | 2.24 | 2.25 | 2.36 | 2.53 |
| 400 | 2.25 | 2.24 | 2.25 | 2.25 | 2.34 | 2.52 |

### Example 13

A semiconductor device was manufactured by substantially the same process as that described in Example except that ultraviolet ray irradiation was performed in a helium atmosphere after damage was repaired with a silane compound subsequently to dry etching and polishing. In particular, ultraviolet ray irradiation was performed subsequently to the repair of damage in such a manner that a layer was irradiated with an ultraviolet ray with a wavelength of 200 to 600 nm for ten minutes using a high-pressure mercury lamp (UVL-7000 H4-N, available from Ushio Inc.) while a substrate was heated at 400° C. in the helium atmosphere.

One million continuous via-holes were measured for yield using multi-level wirings in the semiconductor device manufactured. This showed that the yield of the via-holes was 94%. The effective dielectric constant of an interlayer insulating layer was determined to be 2.58 from interlayer capacitance. The semiconductor device was left at 200° C. for 1000 hours and then measured for wiring resistance. This showed that the resistance thereof was not increased.

### Example 14

A semiconductor device was manufactured by substantially the same process as that described in Example 12 except that ultraviolet ray irradiation was performed in an argon atmosphere after damage was repaired with a silane compound subsequently to dry etching and polishing. In particular, ultraviolet ray irradiation was performed subsequently to the repair of damage in such a manner that a layer was irradiated with an ultraviolet ray with a wavelength of 200 to 600 nm for ten minutes using a high-pressure mercury lamp (UVL-7000 H4-N, available from Ushio Inc.) while a substrate was heated at 400° C. in the helium atmosphere.

One million continuous via-holes were measured for yield using multi-level wirings in the semiconductor device manufactured. This showed that the yield of the via-holes was 93%. The effective dielectric constant of an interlayer insulating layer was determined to be 2.61 from interlayer capacitance. The semiconductor device was left at 200° C. for 1000 hours and then measured for wiring resistance. This showed that the resistance thereof was not increased.

### Example 15

A semiconductor device was manufactured by substantially the same process as that described in Example 12 except that ultraviolet ray irradiation was performed in a vacuum after damage was repaired with a silane compound subsequently to dry etching and polishing. In particular, ultraviolet ray irradiation was performed subsequently to the repair of damage in such a manner that a layer was irradiated with an ultraviolet ray with a wavelength of 200 to 600 nm for ten minutes using a high-pressure mercury lamp (UVL-7000 H4-N, available from Ushio Inc.) while a substrate was heated at 400° C. in a vacuum.

One million continuous via-holes were measured for yield using multi-level wirings in the semiconductor device manufactured. This showed that the yield of the via-holes was 96%. The effective dielectric constant of an interlayer insulating layer was determined to be 2.52 from interlayer capacitance. The semiconductor device was left at 200° C. for 1000 hours and then measured for wiring resistance. This showed that the resistance thereof was not increased.

### Example 16

A semiconductor device was manufactured by substantially the same process as that described in Example 12 except that electron beam irradiation was performed instead of ultraviolet ray irradiation after damage was repaired with a silane compound. In particular, a layer was irradiated with an electron beam at an acceleration voltage of 10 kV for one minute in such a manner that a substrate was heated at 400° C. in a vacuum.

One million continuous via-holes were measured for yield using multi-level wirings in the semiconductor device manufactured. This showed that the yield of the via-holes was 90%. The effective dielectric constant of an interlayer insulating layer was determined to be 2.63 from interlayer capacitance. The semiconductor device was left at 200° C. for 1000 hours and then measured for wiring resistance. This showed that the resistance thereof was not increased.

### Comparative Example 6

A semiconductor device was manufactured by substantially the same process as that described in Example 12 except that no damage was repaired with any, silane compound or no light or electron beam irradiation was performed.

One million continuous via-holes were measured for yield using multi-level wirings in the semiconductor device manufactured. This showed that the yield of the via-holes was 72%. The effective dielectric constant of an interlayer insulating layer was determined to be 2.82 from interlayer capacitance. The semiconductor device was left at 200° C. for 1000 hours and then measured for wiring resistance. This showed that 45% of the via-holes were increased in resistance.

### Comparative Example 7

A semiconductor device was manufactured by substantially the same process as that described in Example 12 except that damage was repaired with a silane compound and no light or electron beam irradiation was performed.

One million continuous via-holes were measured for yield using multi-level wirings in the semiconductor device manufactured. This showed that the yield of the via-holes was 81%. The effective dielectric constant of an interlayer insulating layer was determined to be 2.82 from interlayer capacitance. The semiconductor device was left at 200° C. for 1000 hours and then measured for wiring resistance. This showed that 18% of the via-holes were increased in resistance.

### Example 17

A third wiring layer and other members were formed by the semiconductor device-manufacturing method according to the fifth embodiment. After damage was repaired with a silane compound subsequently to dry etching and polishing, ultraviolet ray irradiation was performed in a nitrogen atmosphere. The third wiring layer was formed under substantially the same process conditions as those for forming a second wiring layer.

One million continuous via-holes were measured for yield using multi-level wirings in a semiconductor device manufactured as described above. This showed that the yield of the via-holes was 94%. The effective dielectric constant of an interlayer insulating layer was determined to be 2.49 from interlayer capacitance. The semiconductor device was left at 200° C. for 1000 hours and then measured for wiring resistance. This showed that the resistance thereof was not increased.

### Example 18

A semiconductor device was manufactured by substantially the same process as that described in Example 17 except that ultraviolet ray irradiation was performed in a helium atmosphere after damage was repaired with a silane compound subsequently to dry etching and polishing. In particular, ultraviolet ray irradiation was performed subsequently to the repair of damage in such a manner that a layer was irradiated with an ultraviolet ray with a wavelength of 200 to 600 nm for ten minutes using a high-pressure mercury lamp (UVL-7000 H4-N, available from Ushio Inc.) while a substrate was heated at 400° C. in the helium atmosphere.

One million continuous via-holes were measured for yield using multi-level wirings in the semiconductor device manufactured. This showed that the yield of the via-holes was 96%. The effective dielectric constant of an interlayer insulating layer was determined to be 2.47 from interlayer capacitance. The semiconductor device was left at 200° C. for 1000 hours and then measured for wiring resistance. This showed that the resistance thereof was not increased.

### Example 19

A semiconductor device was manufactured by substantially the same process as that described in Example 17 except that ultraviolet ray irradiation was performed in an argon atmosphere after damage was repaired with a silane compound subsequently to dry etching and polishing. In particular, ultraviolet ray irradiation was performed subsequently to the repair of damage in such a manner that a layer was irradiated with an ultraviolet ray with a wavelength of 200 to 600 nm for ten minutes using a high-pressure mercury lamp (UVL-7000 H4-N, available from Ushio Inc.) while a substrate was heated at 400° C. in the argon atmosphere.

One million continuous via-holes were measured for yield using multi-level wirings in the semiconductor device manufactured. This showed that the yield of the via-holes was 97%. The effective dielectric constant of an interlayer insulating layer was determined to be 2.47 from interlayer capacitance. The semiconductor device was left at 200° C. for 1000 hours and then measured for wiring resistance. This showed that the resistance thereof was not increased.

### Example 20

A semiconductor device was manufactured by substantially the same process as that described in Example 17 except that ultraviolet ray irradiation was performed in a vacuum after damage was repaired with a silane compound subsequently to dry etching and polishing. In particular, ultraviolet ray irradiation was performed subsequently to the repair of damage in such a manner that a layer was irradiated with an ultraviolet ray with a wavelength of 200 to 600 nm for ten minutes using a high-pressure mercury lamp (UVL-7000 H4-N, available from Ushio Inc.) while a substrate was heated at 400° C. in a vacuum.

One million continuous via-holes were measured for yield using multi-level wirings in the semiconductor device manufactured. This showed that the yield of the via-holes was 95%. The effective dielectric constant of an interlayer insulating layer was determined to be 2.46 from interlayer capacitance. The semiconductor device was left at 200° C. for 1000 hours and then measured for wiring resistance. This showed that the resistance thereof was not increased.

### Example 21

A semiconductor device was manufactured by substantially the same process as that described in Example 17 except that electron beam irradiation was performed instead of ultraviolet ray irradiation after damage was repaired with a silane compound. In particular, a layer was irradiated with an electron beam at an acceleration voltage of 10 kV for one minute in such a manner that a substrate was heated at 400° C. in a vacuum.

One million continuous via-holes were measured for yield using multi-level wirings in the semiconductor device manufactured. This showed that the yield of the via-holes was 93%. The effective dielectric constant of an interlayer insulating layer was determined to be 2.47 from interlayer capacitance. The semiconductor device was left at 200° C. for 1000 hours and then measured for wiring resistance. This showed that the resistance thereof was not increased.

### Comparative Example 8

A semiconductor device was manufactured by substantially the same process as that described in Example 17 except that no damage was repaired with any silane compound or no light or electron beam irradiation was performed.

One million continuous via-holes were measured for yield using multi-level wirings in the semiconductor device manufactured. This showed that the yield of the via-holes was 65%. The effective dielectric constant of an interlayer insulating layer was determined to be 2.76 from interlayer capacitance. The semiconductor device was left at 200° C. for 1000 hours and then measured for wiring resistance. This showed that 58% of the via-holes were increased in resistance.

### Comparative Example 9

A semiconductor device was manufactured by substantially the same process as that described in Example 17 except that damage was repaired with a silane compound and no light or electron beam irradiation was performed.

One million continuous via-holes were measured for yield using multi-level wirings in the semiconductor device manufactured. This showed that the yield of the via-holes was 67%. The effective dielectric constant of an interlayer insulating layer was determined to be 2.75 from interlayer capacitance. The semiconductor device was left at 200° C. for 1000 hours and then measured for wiring resistance. This showed that 26% of the via-holes were increased in resistance.

What is claimed is:

1. A method of manufacturing a semiconductor device, comprising:
forming an insulating layer having silica-based insulating material;
processing the insulating layer;
hydrophobizing the insulating layer by applying a silane compound to act on the insulating layer; and
irradiating the insulating layer with light or an electron beam.

2. The method according to claim 1, wherein the processing the insulating layer is performed by dry-etching the insulating layer.

3. The method according to claim 1, wherein the processing the insulating layer is performed by polishing the insulating layer.

4. The method according to claim 1, further comprising treating the insulating layer with plasma generated from oxygen, argon, hydrogen, nitrogen, or a gas mixture of some selected from oxygen, argon, hydrogen, and nitrogen, before the forming the insulating layer comprising the silica-based insulating material, and after the hydrophobizing the insulating layer by applying the silane compound to act on the insulating layer.

5. The method according to claim 4, wherein the treating the insulating layer with plasma generated from oxygen, argon, hydrogen, nitrogen, or a gas mixture of some selected from oxygen, argon, hydrogen, and nitrogen removes a by-product from the insulating layer generated by the processing the insulating layer.

6. The method according to claim 1, further comprising removing the by-product from the insulating layer generated by the processing the insulating layer using a chemical solution before the forming the insulating layer comprising the silica-based insulating material, and after the hydrophobizing the insulating layer by applying the silane compound to act on the insulating layer.

7. The method according to claim 1, wherein the irradiating the insulating layer with light or the electron beam is performed at a temperature of 30° C. to 400° C.

8. The method according to claim 1, wherein the irradiating the insulating layer with light or the electron beam is performed in an atmosphere with an oxygen content of 150 ppm or less.

9. The method according to claim 8, wherein the atmosphere contains one or more of nitrogen, helium, and argon.

10. The method according to claim 8, wherein the atmosphere is vacuumed.

11. The method according to claim 1, wherein the hydrophobizing the insulating layer by applying the silane compound to act on the insulating layer is performed at a temperature of 20° C. to 350° C.

12. The method according to claim 1, wherein the hydrophobizing the insulating layer by applying the silane compound to act on the insulating layer applies a vapor containing the silane compound on the insulating layer.

13. The method according to claim 1, wherein the hydrophobizing the insulating layer by applying the silane compound to act on the insulating layer applies the silane compound by a spin coating on the insulating layer.

14. The method according to claim 13, further comprising heating the insulating layer at a at a temperature of 50° C. to 350° C. after applying the silane compound by the spin coating on the insulating layer.

15. The method according to claim 1, wherein the silane compound is a silazane compound, an amidosilane compound, an alkoxysilane compound, or an acetoxysilane compound.

16. The method according to claim 1, wherein the insulating layer is a laminate comprising a silica-based porous insulating layer.

17. The method according to claim 1, wherein the insulating layer is a laminate comprising a SiOC layer formed by a plasma-enhanced CVD process.

18. A method of manufacturing a semiconductor device, comprising:
forming an insulating layer comprising silica-based insulating material on a semiconductor substrate;
forming an opening in the insulating layer by dry etching;
forming a conductive layer over the insulating layer and the opening;
forming a wiring including a portion of the conductive layer disposed in the opening by partly removing the conductive layer by polishing the conductive layer over the insulating layer;
hydrophobizing the insulating layer by applying a silane compound to act on the insulating layer; and
irradiating the insulating layer with light or an electron beam;
wherein the hydrophobizing the insulating layer by applying the silane compound to act on the insulating layer;
and the irradiating the insulating layer with light or the electron beam are performed between the forming an opening in the insulating layer by dry etching and the forming the conductive layer over the insulating layer and the opening, or after the forming the wiring including the portion of the conductive layer disposed in the opening by partly removing the conductive layer by polishing the conductive layer over the insulating layer.

19. The method according to claim 18, wherein the forming the insulating layer comprising silica-based insulating material on the semiconductor substrate forms a first insulating layer and a second insulating layer, the second insulating layer being formed on the first insulating layer, and the forming the wiring including the portion of the conductive layer disposed in the opening by partly removing the conductive layer by polishing the conductive layer over the insulating layer removes the second insulating layer and the conductive layer.

20. The method according to claim 19, wherein the second insulating layer is a hard mask when the forming the wiring including the portion of the conductive layer disposed in the opening by partly removing the conductive layer by polishing the conductive layer over the insulating layer.
